(19) United States
(12) Patent Application Publication
(10) Pub. No.: US 2025/0081835 A1
(43) Pub. Date: Mar. 6, 2025

(54) PHOSPHORESCENT MATERIAL, ELECTROLUMINESCENT DEVICE AND DISPLAY DEVICE

(71) Applicant: BOE Technology Group Co., Ltd., Beijing (CN)

(72) Inventors: Yansong Li, Beijing (CN); Shuyun Xu, Beijing (CN)

(73) Assignee: BOE Technology Group Co., Ltd., Beijing (CN)

(21) Appl. No.: 18/579,912

(22) PCT Filed: May 9, 2023
(86) PCT No.: PCT/CN2023/093088

§ 371 Date: Jan. 17, 2024

(51) Int. Cl. H10K 85/30; C09K 11/02; C09K 11/06; H10K 85/60

(52) U.S. Cl. CPC H10K 85/342; C09K 11/02; C09K 11/06; H10K 85/615; H10K 85/653; H10K 85/654; H10K 85/655

(57) ABSTRACT

The present disclosure relates to the field of display technology, in particular to a phosphorescent material, an electroluminescent device and a display device. The phosphorescent material includes a heterocyclic ligand phosphorescent iridium complex with a structural formula indicated by general formula I.

### TECHNICAL FIELD

Embodiments of the present disclosure relate to the field of display technology, in particular to a phosphorescent material, an electroluminescent device and a display device.

### BACKGROUND

Organic light emitting diodes (OLED) have a very wide application market due to advantages thereof, such as the characteristics of all-solid-state, autonomous light emitting, high brightness, high resolution, wide viewing angle, fast response, thin thickness, small size, light weight, adopting flexible substrates, low voltage DC drive, low power consumption, and wide operating temperature range. The phosphorescent material used as the light emitting layer of the OLED device enables the singlet exciton and the triplet exciton to jointly participate in luminescence, so that the device has an internal quantum efficiency that can theoretically reach 100%, and has a high external quantum efficiency. Therefore, the OLED device has a wide application prospect.

### SUMMARY

The present disclosure adopts technical solutions described below.

A first aspect of the present disclosure provides a phosphorescent material, including a heterocyclic ligand phosphorescent iridium complex with a structural formula indicated by general formula I below:

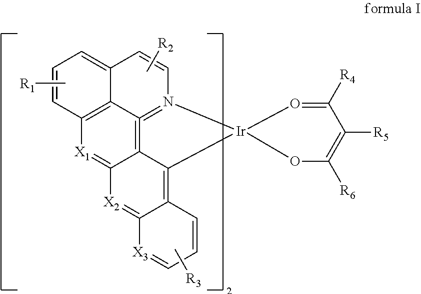

where X₁ is O or S, X₂ and X₃ are each independently selected from N or C; R₁, R₂, R₃, R₄, R₅ and R₆ are each independently selected from hydrogen, deuterium, halogen, cyanogroup, nitro, hydroxy, amino, sulfonic acid group, sulfonyl group, phosphoryl group, substituted or unsubstituted C1-C60 Alkyl group, substituted or unsubstituted C6-C60 aryl group, substituted or unsubstituted C3-C30 cycloalkyl group, substituted or unsubstituted C1-C60 alkoxy group, substituted or unsubstituted C1-C60 alkylamine group, substituted or unsubstituted C2-C60 alkenyl, substituted or unsubstituted C2-C60 alkynyl, substituted or unsubstituted C5-C60 heterocyclyl, substituted or unsubstituted C10-C60 condensed cyclic group or substituted or unsubstituted C5-C60 spirocyclic group.

In an optional embodiment, a lifetime of excitons of the heterocyclic ligand phosphorescent iridium complex is less than or equal to 1 μs.

In an optional embodiment, a ratio of current efficiency of the electroluminescent device at a peak luminance of 16,000 nits to the current efficiency of the electroluminescent device at the peak luminance of 1,300 nits is less than or equal to 0.8, the electroluminescent device includes a light emitting layer, and the material of the light emitting layer includes the heterocyclic ligand phosphorescent iridium complex.

In an optional embodiment, substitution positions of R₁, R₂ and R₃ are at any position where a ring thereof is located, R₁ and R₃ represent monosubstituted group, bi-substituted group, tri-substituted group or no substituent, R₂, R₅ represent monosubstituted group, bi-substituted group or no substituent, and R₄ and R₆ represent monosubstituted group or no substituent.

In an optional embodiment, any adjacent R₁, R₂, R₃ substituent groups form a condensed ring or aromatic heterocyclic ring with the ring where they located, R₁, R₂ and R₃ that do not form a condensed ring or aromatic heterocyclic ring are each independently selected from any one of hydrogen, deuterium, substituted or unsubstituted C1-C60 alkyl group, substituted or unsubstituted C6-C60 aryl group, substituted or unsubstituted C3-C60 cycloalkyl group, substituted or unsubstituted C5-C60 heterocyclyl group, substituted or unsubstituted C10-C60 condensed cyclic group, substituted or unsubstituted C5-C60 spirocyclic group.

In an optional embodiment, R₁, R₂, R₃, R₄, R₅ and R₆ are each independently selected from any one of hydrogen, deuterium, substituted or unsubstituted C1-C30 alkyl, substituted or unsubstituted C3-C20 cycloalkyl, substituted or unsubstituted C1-C20 alkoxy group, substituted or unsubstituted C5-C30 heterocyclic group, substituted or unsubstituted C6-C30 aryl group, substituted or unsubstituted C10-C30 condensed ring group.

In an optional embodiment. R₁ is any one of tert-butyl, methyl, and hydrogen; R₂ is any one of methyl, hydrogen, and deuterium; R₃ is any one of hydrogen, methyl, and tert-butyl; R₄ is any one of hexyl, methyl and isopropyl; R₅ is hydrogen; R₆ is any one of hexyl, methyl and isopropyl.

In an optional embodiment, the heterocyclic ligand phosphorescent iridium complex is selected from any one of the following complexes:

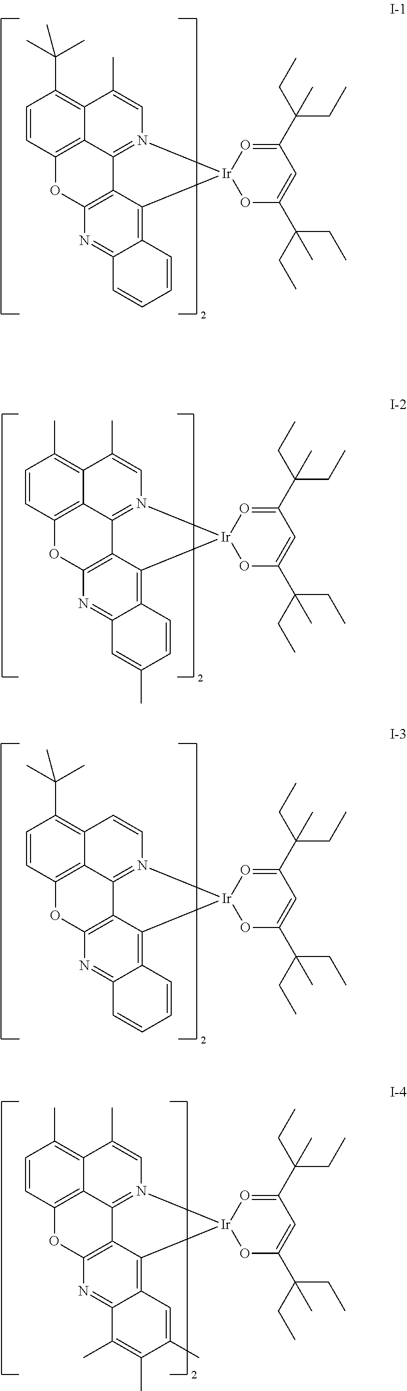

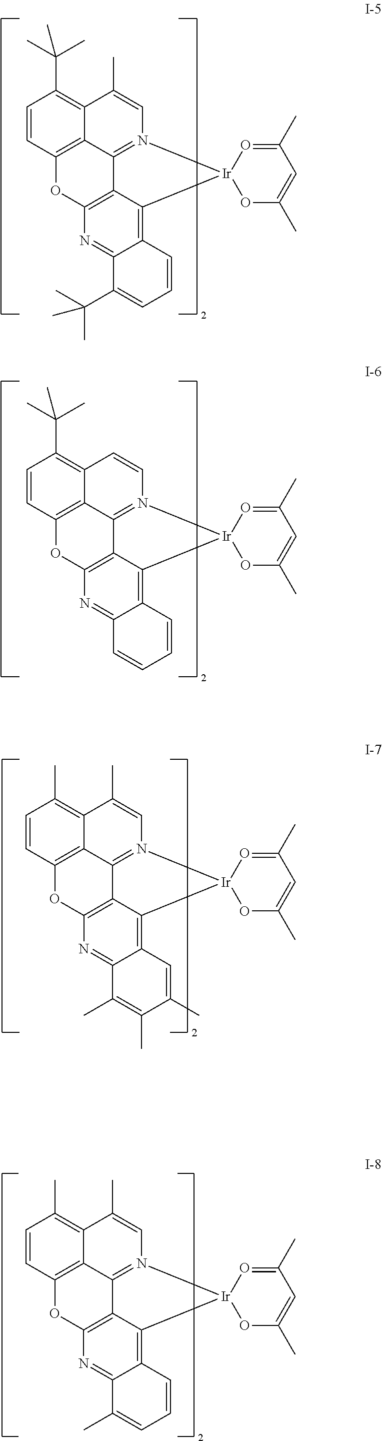

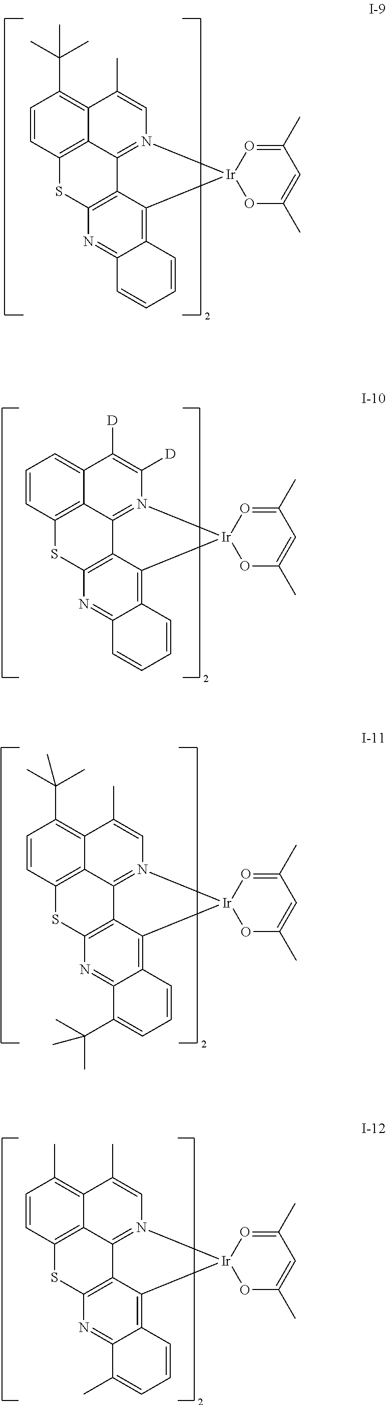

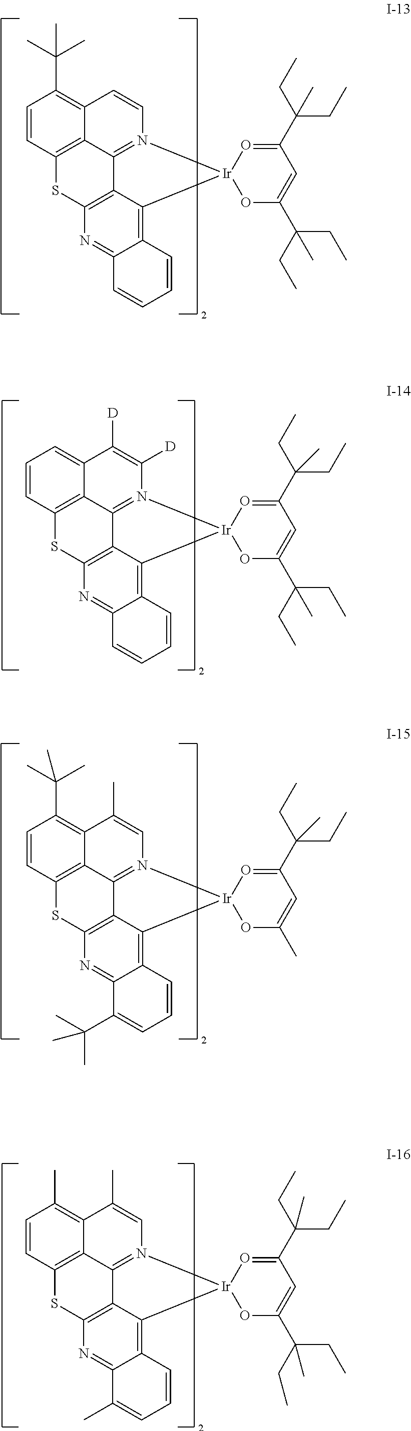

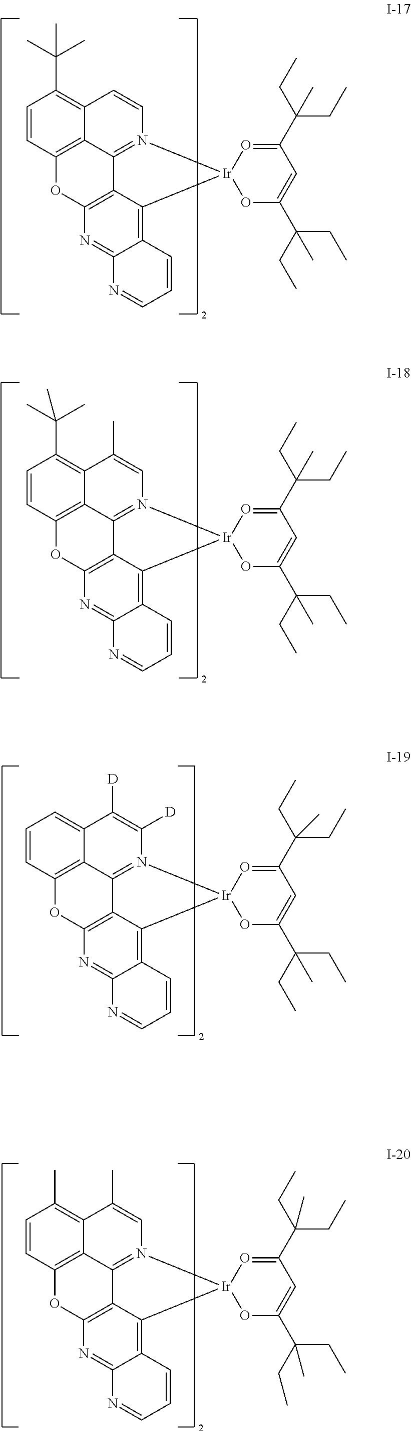

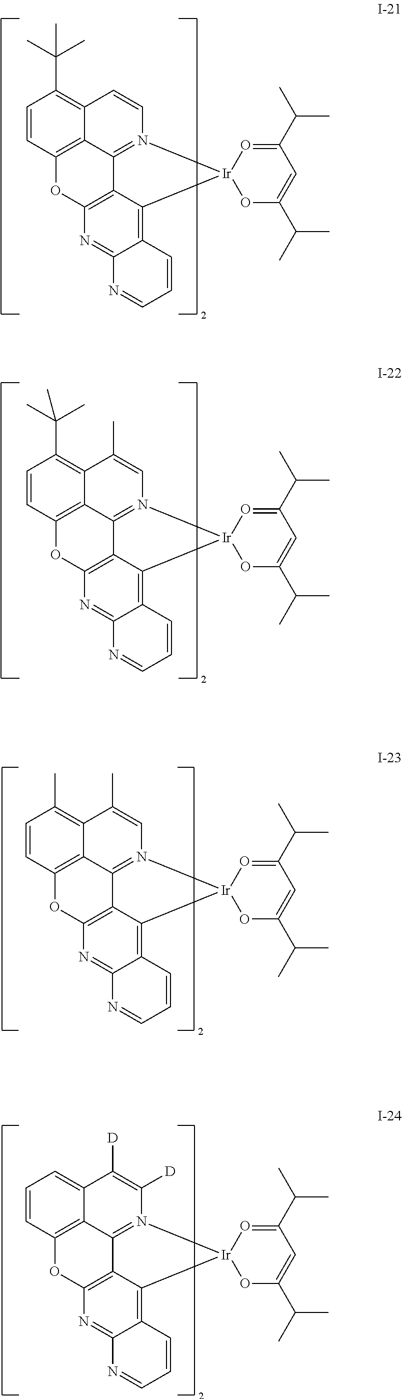

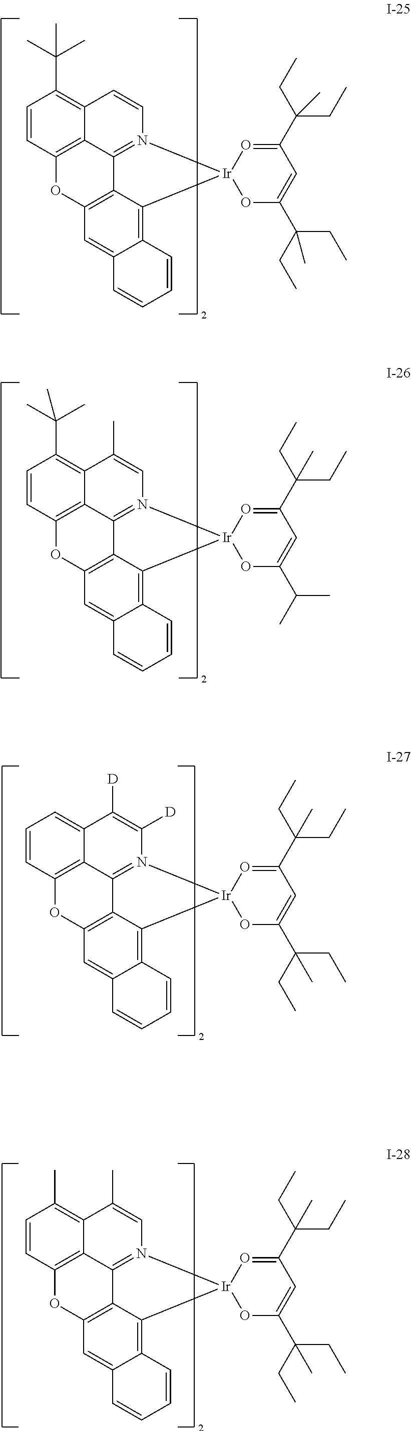

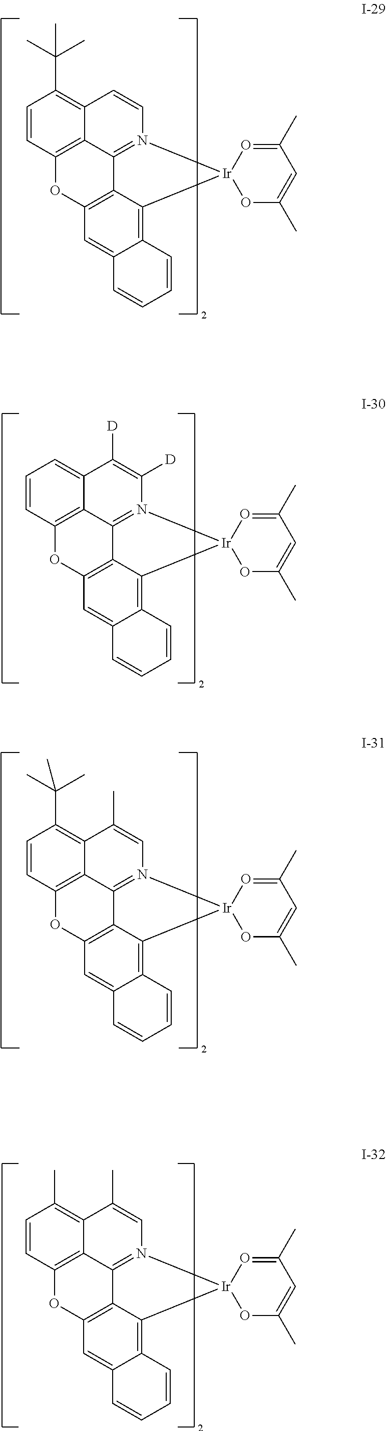

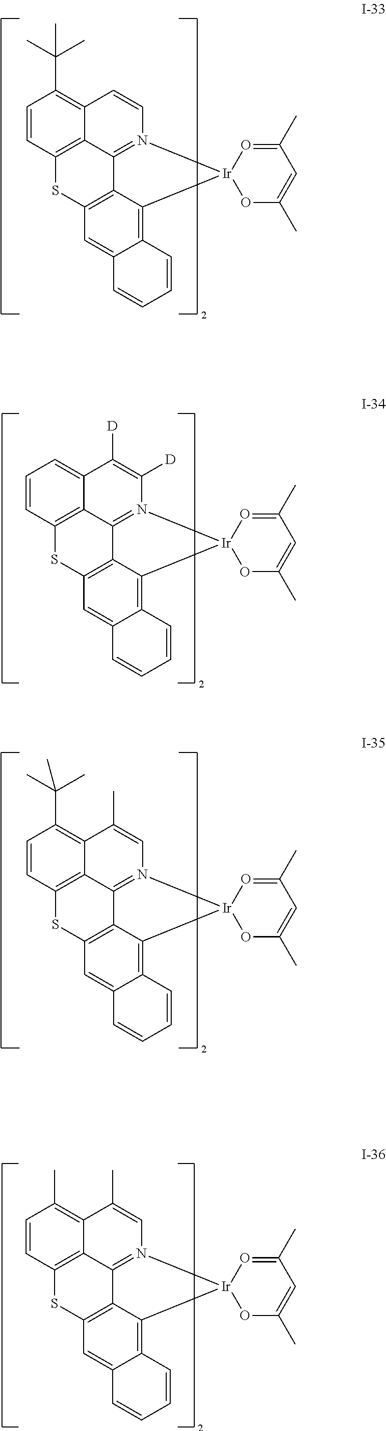

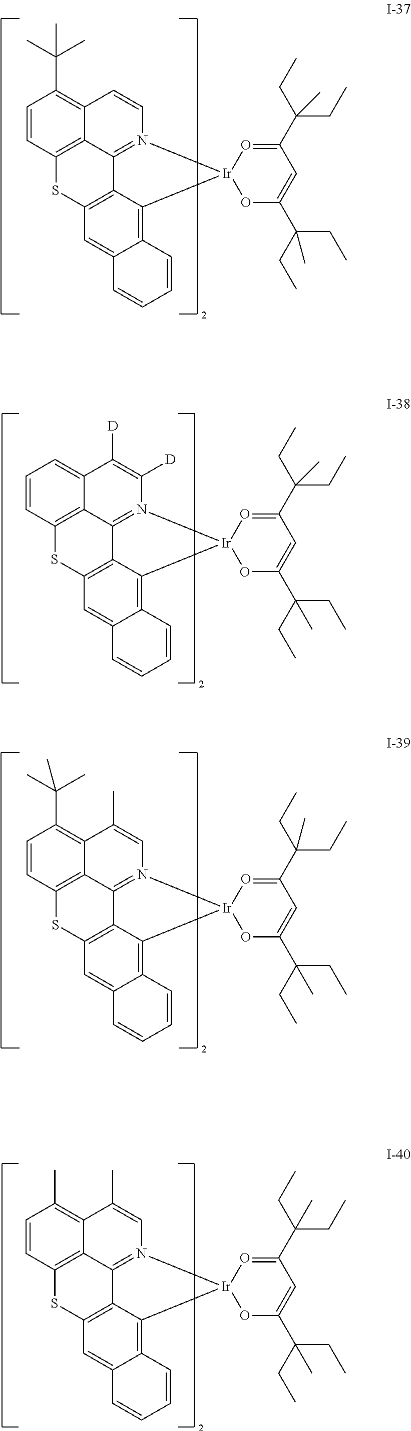

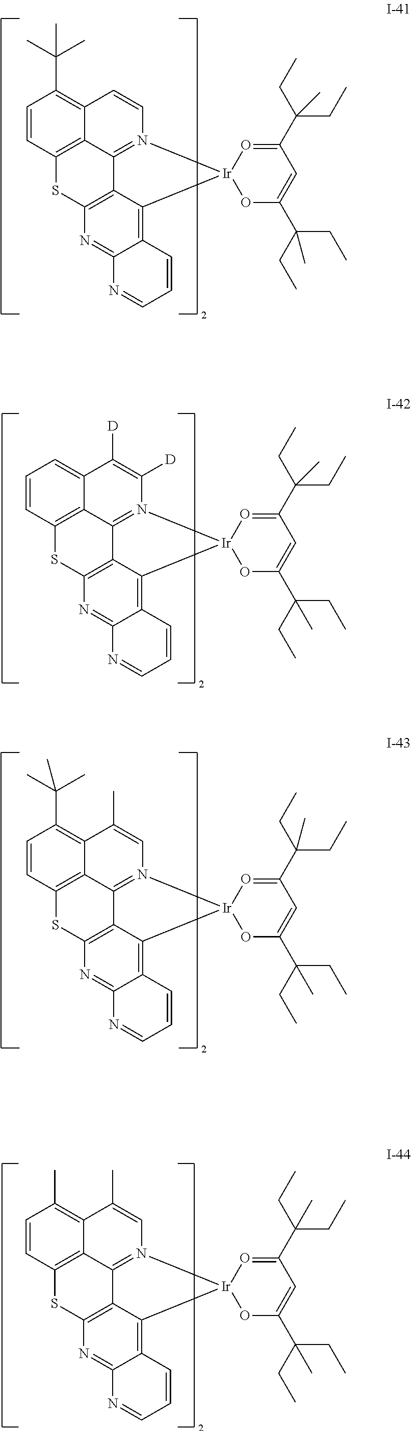

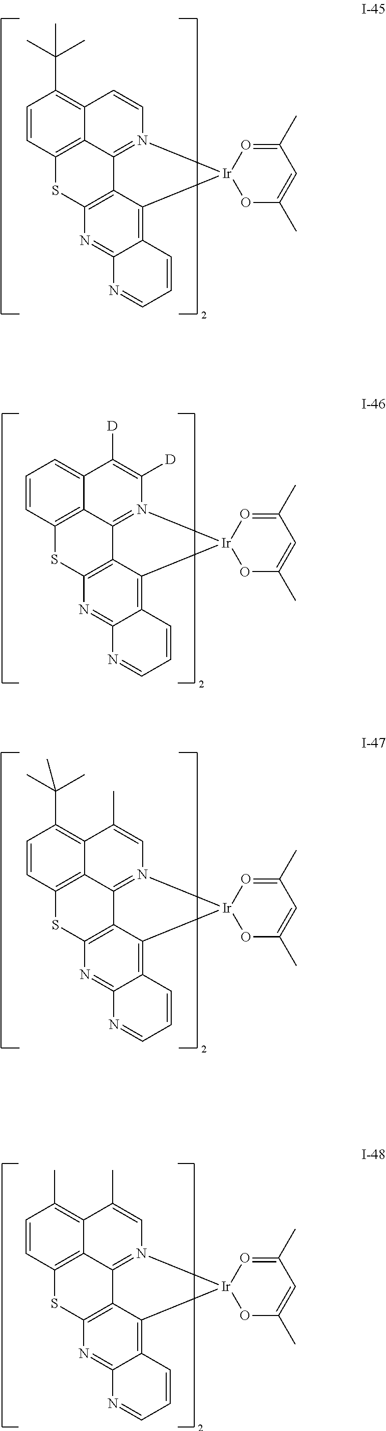

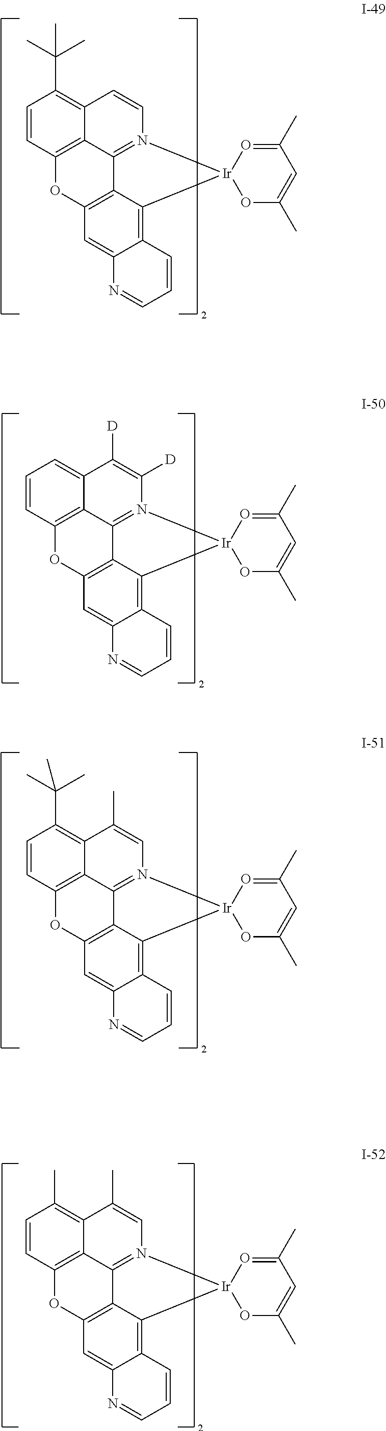

A second aspect of the present disclosure provides an electroluminescent device, including:
an anode, a cathode and at least one fight emitting layer, the light emitting layer is disposed between the anode and the cathode, the fight emitting layer includes any phosphorescent material described in the first aspect;
the light emitting layer includes a host luminescent material and a guest luminescent material, and at least one of the host luminescent material and the guest luminescent material is the phosphorescent material.

In an optional implementation, the electroluminescent device includes:
a hole injection layer, a first hole transport layer and a first electron blocking layer that are sequentially disposed between the anode and the first fight emitting layer along a first direction, the first direction being a direction pointing to the cathode from the anode;
a hole blocking layer, an electron transport layer, and an electron injection layer that are disposed sequentially between the light emitting layer and the cathode along the first direction.

In an optional implementation,
a thickness of the electron injection layer is in a range of 0.5 nm to 3 nm;
the thickness of the electron transport layer is in a range of 20 nm to 35 nm;
the thickness of the electron blocking layer is in a range of 5 nm to 80 nm;
the thickness of the luminescent layer is in a range of 30 nm to 50 nm;
the thickness of the hole blocking layer is in a range of 5 nm to 10 nm;
the thickness of the hole transport layer is in a range of 80n to 130 nm;
the thickness of the hole injection layer is in a range of 5 nm to 30 nm.

In an optional implementation, the light emitting layer includes:
a first light emitting layer and a second light emitting layer, the material of at least one of the first light emitting layer and the second light emitting layer is any phosphorescent material according to the first aspect.

In an optional implementation, the electroluminescent device includes:
a charge generation layer, disposed between the first light emitting layer and the second light emitting layer, the charge generation layer includes a p-type charge generation layer and n-type charge generation layer;
a hole injection layer, a first hole transport layer and a first electron blocking layer that are sequentially disposed between the anode and the first light emitting layer along a first direction, wherein the first direction is a direction pointing to the cathode from the anode;
a second hole blocking layer, a second electron transport layer and an electron injection layer that are sequentially disposed between the cathode and the second light emitting layer along the first direction;
a first hole blocking layer disposed between the first light emitting layer and the n-type charge generation layer;
a second hole transport layer and a second electron blocking layer that are sequentially disposed between the p-type charge generation layer and the second light emitting layer along the first direction.

In an optional implementation, the electroluminescent device further includes a first electron transport layer disposed between the n-type charge generation layer and the first hole blocking layer;
a thickness of the electron injection layer is in a range of 0.5 nm to 3 nm;
the thicknesses of the first electron transport layer and the second electron transport layer are in a range of 20 nm to 35 nm;
the thicknesses of the first electron blocking layer and the second electron blocking layer are in a range of 5 nm to 80 nm;
the thicknesses of the first light emitting layer and the second light emitting layer is in a range of 30 nm to 50 nm;
the thicknesses of the first hole blocking layer and the second hole blocking layer are in a range of 5 nm to 10 nm;
the thicknesses of the first hole transport layer and the second hole transport layer are in a range of 80 nm to 130 nm;
the thickness of the hole injection layer is in a range of 5 nm to 30 nm;
the thickness of the p-type charge generation layer is in a range of 8 nm to 10 nm;
the thickness of the n-type charge generation layer is in a range of 17 nm to 19 nm.

A third aspect of the present disclosure provides a display device including any electroluminescent device according to the second aspect.

The above explanation is merely an overview of technical solutions of the present disclosure. In order to make the technical means of the present disclosure be learned more clearly and make solutions of the present disclosure be implemented according to the contents of the specification, and in order to make the above-mentioned and other objects, features and advantages of the present disclosure more apparent and understandable, specific implementations of the present disclosure are set forth below.

### BRIEF DESCRIPTION OF THE DRAWINGS

In order to describe technical solutions in embodiments of the present disclosure or the related art more clearly, the accompanying drawings which are used in the description of the embodiments or the related art will be briefly introduced. Apparently, the accompanying drawings in the following description illustrate some embodiments of the present disclosure, based on these accompanying drawings, those skilled in the art may obtain other accompanying drawings without paying any creative effort.

FIG. 1 is a schematic diagram schematically illustrating an electroluminescent device proposed by the present disclosure;

FIG. 2 is a diagram schematically illustrating a current efficiency-luminance curve of an electroluminescent device proposed by the present disclosure;

FIG. 3 is a schematic diagram schematically illustrating a tandem electroluminescent device proposed by the present disclosure; and

FIG. 4 is a schematic diagram schematically illustrating another tandem electroluminescent device proposed by the present disclosure.

### REFERENCE SIGNS

101. Cathode; 102. Electron injection layer; 103. Electron transport layer; 103-1. First electron transport layer; 103-2. Second electron transport layer; 104. Hole blocking layer; 104-1. First hole blocking layer; 104-2. Second hole blocking layer; 105. Emitting Layer; 105-1. First emitting layer; 105-2. Second emitting layer; 106. Electron blocking layer; 106-1. First electron blocking layer; 106-2. Second electron blocking layer; 107. Hole transport layer; 107-1. First hole transport layer; 107-2. Second hole transport layer; 108. Hole injection layer; 109. Anode; 110. Charge generation layer; 110-1. p-type charge generation layer; 110-2. n-type charge generation layer.

### DETAILED DESCRIPTION OF THE EMBODIMENTS

In order to make objects, solutions and advantages of embodiments of the present disclosure clearer, a clear and thorough description for technical solutions in the embodiments of the present disclosure will be given below in conjunction with the accompanying drawings in the embodiments of the present disclosure. Apparently, the described embodiments are a part of embodiments of the present disclosure, not all the embodiments. All other embodiments obtained, based on the embodiments in the present disclosure, by those skilled in the art without paying creative effort fall within the protection scope of the present disclosure.

Organic light emitting diodes (OLED) have a very wide application market due to advantages thereof, such as the characteristics of all-solid-state, autonomous light emitting, high brightness, high resolution, wide viewing angle (greater than 170°), fast response, thin thickness, small size, light weight, adopting flexible substrates, low voltage DC drive (3-10V), low power consumption, and wide operating temperature range. For example, organic light emitting diodes may be used in an illuminating system, a communication system, a vehicle display, a portable electronic device, a high-definition display and even the military field.

Driven by the OLED voltage, holes are injected to the highest occupied molecular orbital (HOMO) of the organic material from the anode, and electrons are injected to the lowest unoccupied molecular orbital (LUMO) of the organic material from the cathode. The holes and electrons move in the organic layer. After the hole and electron meet, they recombine to generate excitons. Then, the excitons continue to diffuse freely in the organic solid film, and are deactivated in the form of radiation and radiationless, that is, the excitons return to the ground state from the upper state (excited state). During this process, energy will be released in the form of light, so that the device emits light. During this process, excitons need to recombine in the middle of the light emitting layer to emit light efficiently. Therefore, the injection and migration of electrons and holes in the organic material have to be balanced. It has always been pursued in the field to improve the efficiency of the organic light emitting diode device and prolong the service life of the organic light emitting diode device.

The phosphorescent material enables singlet excitons and triplet excitons to jointly participate in luminescence, so that the device has an internal quantum efficiency that may theoretically reach 100%, and has a high external quantum efficiency. Therefore, the device has a wide application prospect. However, most high efficiency phosphorescent devices face a common problem that the external quantum efficiency decreases drastically (that is, efficiency roll-off) as the brightness increases. The efficiency roll-off of the phosphorescent device is mainly due to exciton annihilation, including triplet-triplet annihilation (TTA) and exciton-polaron annihilation (TPA). Therefore, in order to further promote the commercial application of OLED devices, it is necessary to provide effective and universal new device structures to suppress the efficiency roll-off of the OLED device.

In view of this, the present disclosure proposes a phosphorescent material, including:
a heterocyclic ligand phosphorescent iridium complex with a structural formula indicated by general formula I below:

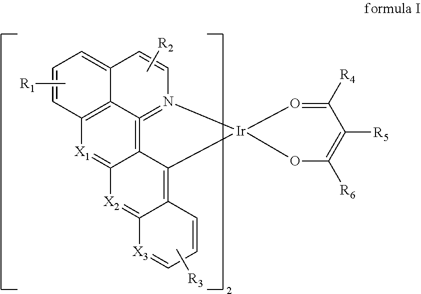

where X₁ is O or S, X₂ and X₃ are independently selected from N or C respectively; R₁, R₂, R₃, R₄, R₅ and R₆ are each independently selected from hydrogen, deuterium, halogen, cyanogroup, nitro, hydroxy, amino, sulfonic acid group, sulfonyl group, phosphoryl group, substituted or unsubstituted C1-C60 Alkyl group, substituted or unsubstituted C6-C60 aryl group, substituted or unsubstituted C3-C30 cycloalkyl group, substituted or unsubstituted C1-C60 alkoxy group, substituted or unsubstituted C1-C60 alkylamine group, substituted or unsubstituted C2-C60 alkenyl, substituted or unsubstituted C2-C60 alkynyl, substituted or unsubstituted C5-C60 heterocyclyl, substituted or unsubstituted C10-C60 condensed cyclic group or substituted or unsubstituted C5-C60 spirocyclic group.

It should be noted that, in the embodiment of the present disclosure, the aryl group includes, but is not limited to, phenyl, naphthyl, anthryl, acenaphthylenyl, indenyl, phenanthrenyl, azulenyl, pyrenyl, fluorenyl, perylene, spirofluorenyl, spirobifluorenyl, phenyl, benzophenanthryl, benzanthracenyl, fluoranthene, benzyl, tetraphenyl and indenyl.

Metal complexes generally have three types of excited states, that is, the metal center electronic (MC), the metal-to-ligand charge transfer (MLCT) excited state, the Π-Π* transition excited state at the ligand center (LC). The former's triplet emission may be divided into two categories: the triplet metal-to-ligand charge transfer (3MLCT) transition radiation, and the mixing transition radiation of 3MLCT and triplet 11 electrons (3LC) between ligands. For phosphorescent iridium complexes, no matter whether it is 3MLCT or 3LC transition radiation, LUMO is located on the neutral ligand (C\hat{ }N). Therefore, the LUMO energy level of the molecule may be adjusted as long as the type or structure of the ligand (C\hat{ }N) is changed, thereby achieving the modulation of the luminescence wavelength of the phosphorescent material.

Generally, the emission wavelength of the heterocyclic ligand iridium complex (C\hat{ } N)₂ Ir(L\hat{ }L) may be adjusted in two ways: modulating the emission wavelength of the organic phosphorescent material by changing the structure of the ligand (C\hat{ }N), or achieving the same purpose by adjusting the structure of the auxiliary ligand (L\hat{ }L) (provided that the MLCT or LC triplet energy level may be higher than the triplet energy level of the auxiliary ligand, that is, the LUMO is distributed in the auxiliary ligand). In the embodiments of the present disclosure, the structure of the ligand (C\hat{ }N) is changed through R₁, R₂ and R₃ as well as X₁, X₂ and X₃, and the structure of the auxiliary ligand (L\hat{ }L) is changed through R₄, R₅ and R₆, thereby achieving the modulation of the emission wavelength of the heterocyclic ligand phosphorescent iridium complex, reducing the exciton lifetime of the heterocyclic ligand phosphorescent iridium complex and reducing the drop degree of the efficiency. Electroluminescent devices adopting the heterocyclic ligand phosphorescent iridium complexes provided by embodiments of the present disclosure have excellent color purity and brightness as well as extended durability.

In the embodiments of the present disclosure, the lifetime of excitons of the heterocyclic ligand phosphorescent iridium complexes is less than or equal to 1 μs. Therefore, the electroluminescent device adopting the heterocyclic ligand phosphorescent iridium complexes can effectively improve the problem of display color shift caused by efficiency roll-off under the high current density of the panel in the later stage of the module.

For an electroluminescent device adopting the heterocyclic ligand phosphorescent iridium complexes described in the present disclosure as the material of the light emitting layer, a ratio of the current efficiency thereof at a peak luminance of 16,000 nits to the current efficiency thereof at a peak luminance of 1,300 nits is less than or equal to 0.8. This shows that the amplitude of the efficiency roll-off of the electroluminescent device adopting the heterocyclic ligand phosphorescent iridium complexes described in the present disclosure as the material of the light emitting layer is small. Therefore, the electroluminescent device can effectively improve the current efficiency and improve the problem of display color shift caused by efficiency roll-off. On the contrary, for electroluminescent devices that do not adopt the heterocyclic ligand phosphorescent iridium complexes described in the present disclosure as the material of the light emitting layer, the ratio of the current efficiency thereof at the peak luminance of 16,000 nits to the current efficiency thereof at the peak luminance of 1,300 nits is greater than 0.8; in this case, the efficiency roll-off of such electroluminescent device is large, and the current efficiency of the device will significantly decrease as the luminance increases, resulting in the display color shift problem.

In an optional embodiment, the substitution positions of R₁, R₂ and R₃ are at any position where a ring thereof is located, R₁ and R₃ represent monosubstituted groups, bi-substituted groups, tri-substituted groups or no substituents, R₂, R₅ represent monosubstituted groups, bi-substituted groups or no substituents, and R₄ and R₆ represent monosubstituted groups or no substituents.

In an optional implementation, any adjacent R₁, R₂, R₃ substituent groups form a condensed ring or aromatic heterocyclic ring with the ring where they located. R₁, R₂ and R₃ that do not form a condensed ring or aromatic heterocyclic ring are each independently selected from any one of hydrogen, deuterium, substituted or unsubstituted C1-C60 alkyl group, substituted or unsubstituted C6-C60 aryl group, substituted or unsubstituted C3-C60 cycloalkyl group, substituted or unsubstituted C5-C60 heterocyclyl group, substituted or unsubstituted C10-C60 condensed cyclic group, substituted or unsubstituted C5-C60 spirocyclic group.

In an optional implementation, R₁, R₂, R₃, R₄, R₅ and R₆ are each independently selected from any one of hydrogen, deuterium, substituted or unsubstituted C1-C30 alkyl, substituted or unsubstituted C3-C20 cycloalkyl, substituted or unsubstituted C1-C20 alkoxy group, substituted or unsubstituted C5-C30 heterocyclic group, substituted or unsubstituted C6-C30 aryl group, substituted or unsubstituted C10-C30 condensed cyclic group.

In an optional implementation. R₁ is any one of tert-butyl, methyl, and hydrogen; R₂ is any one of methyl, hydrogen, and deuterium; R₃ is any one of hydrogen, methyl, and tert-butyl; R₄ is any one of hexyl, methyl and isopropyl; R₅ is hydrogen; R₆ is any one of hexyl, methyl and isopropyl.

In an optional implementation, the heterocyclic ligand phosphorescent iridium complex is selected from any one of the following complexes:

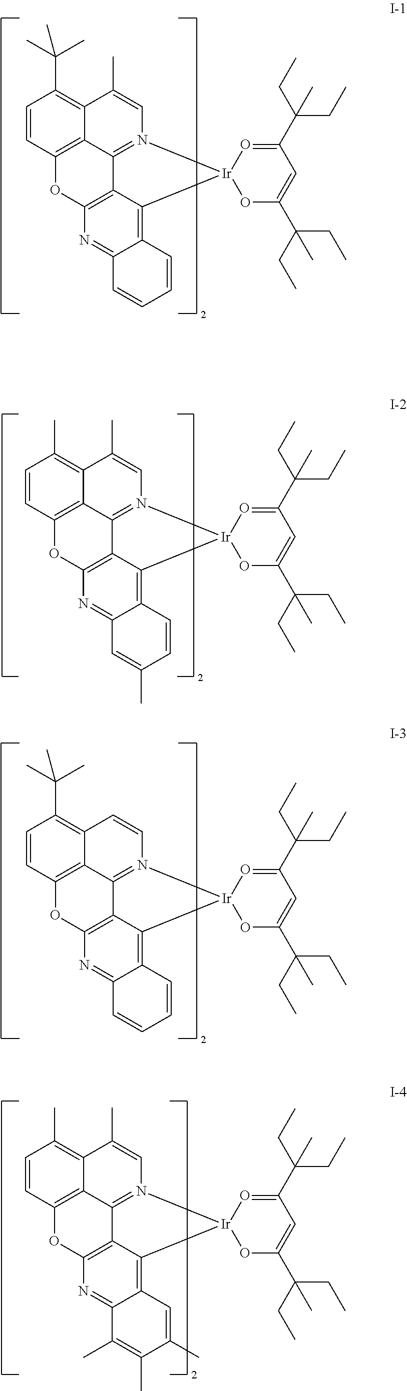

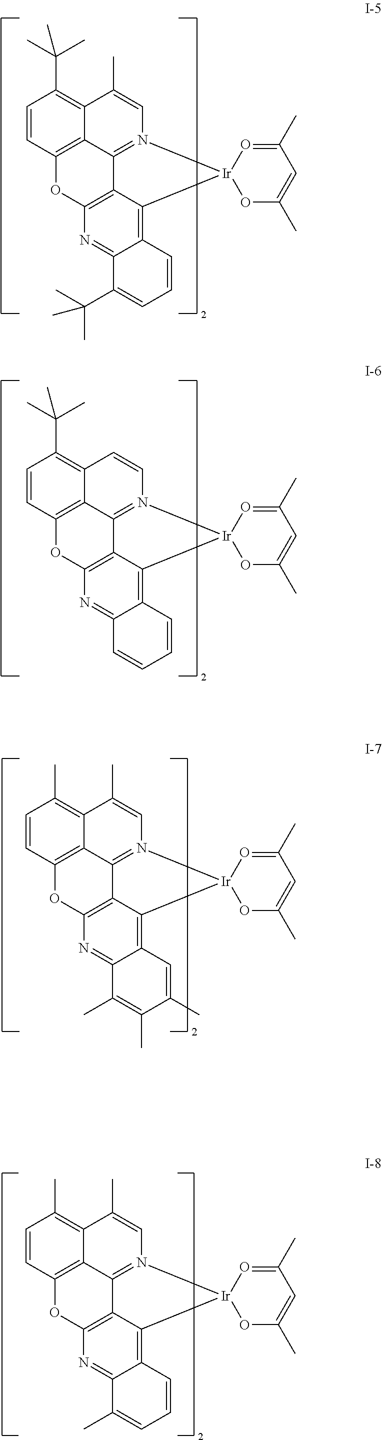

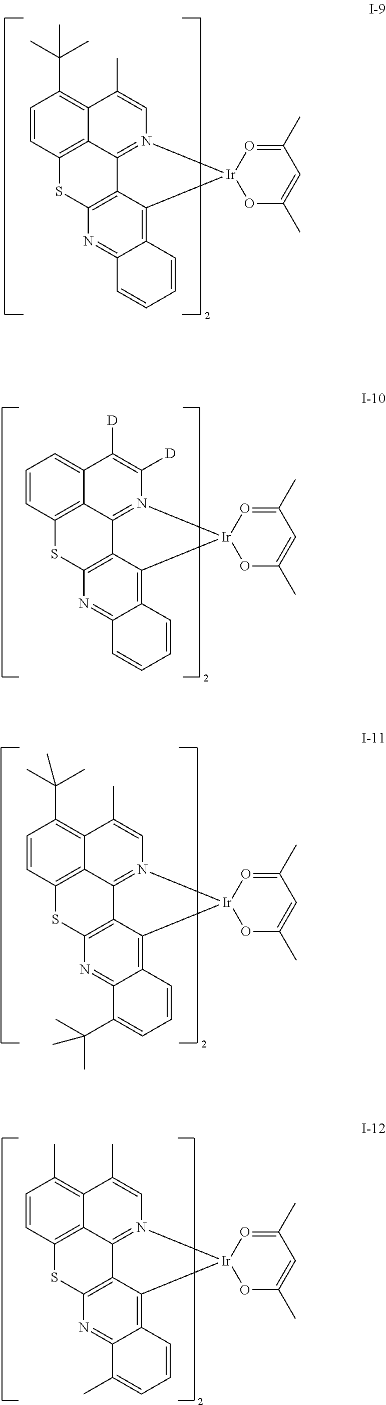

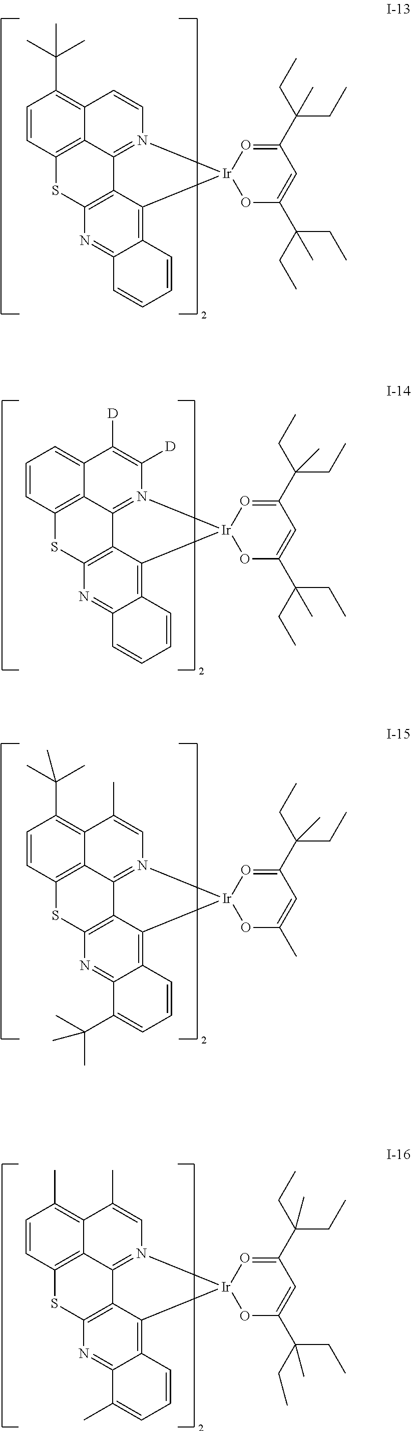

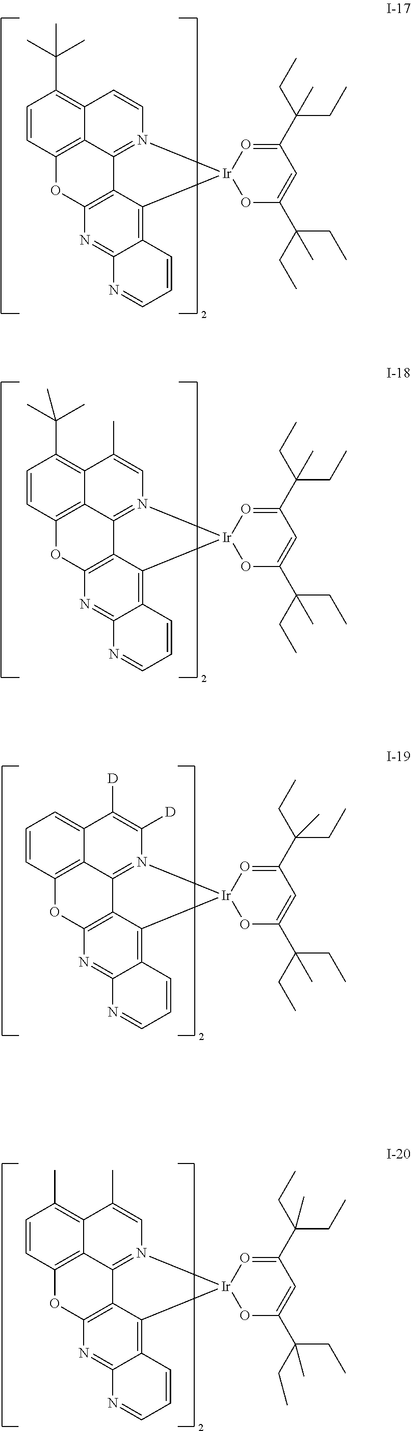

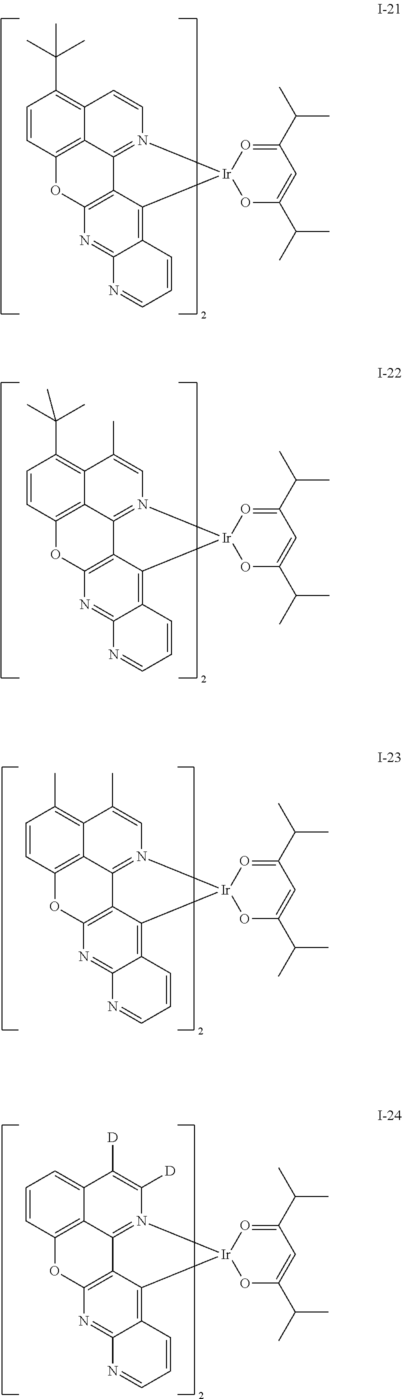

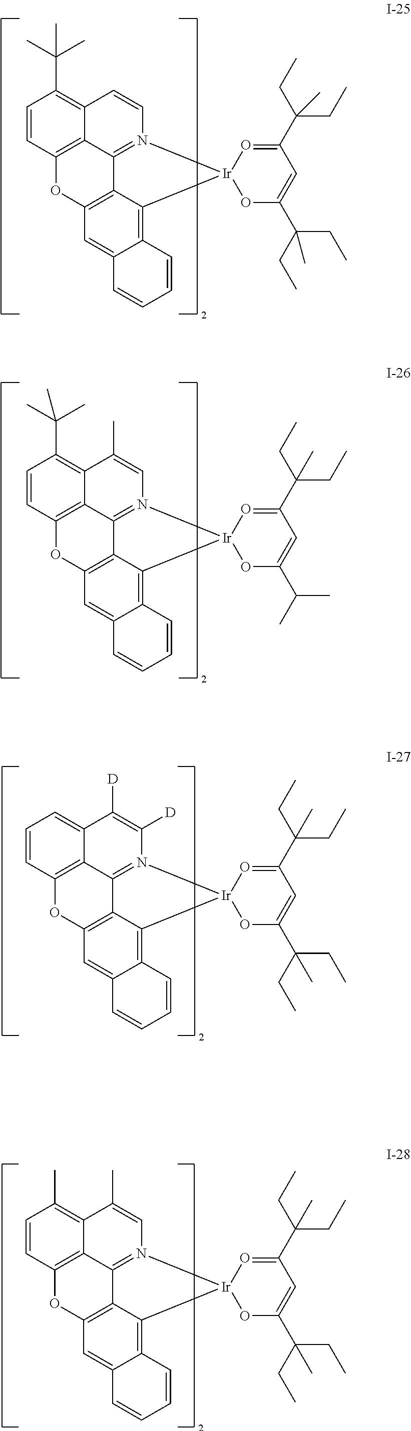

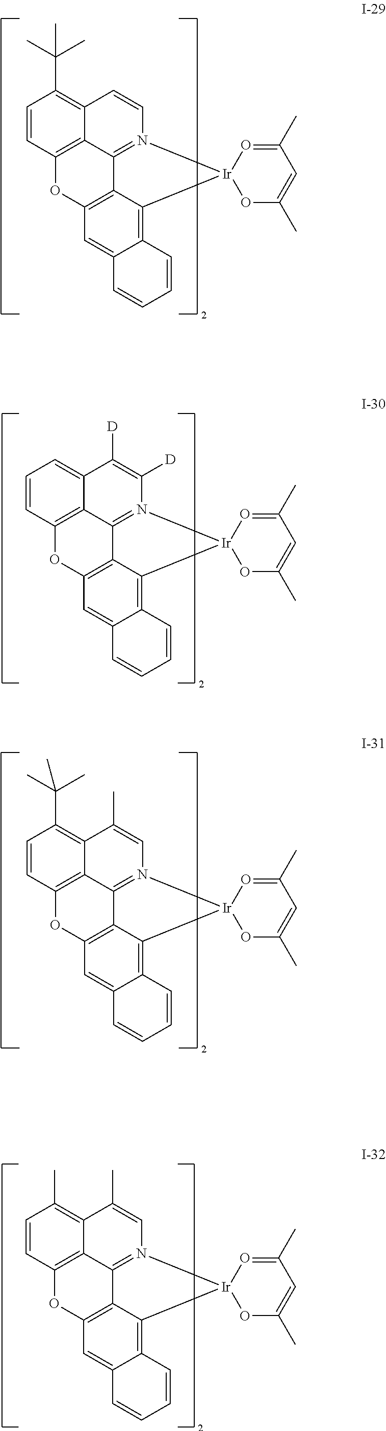

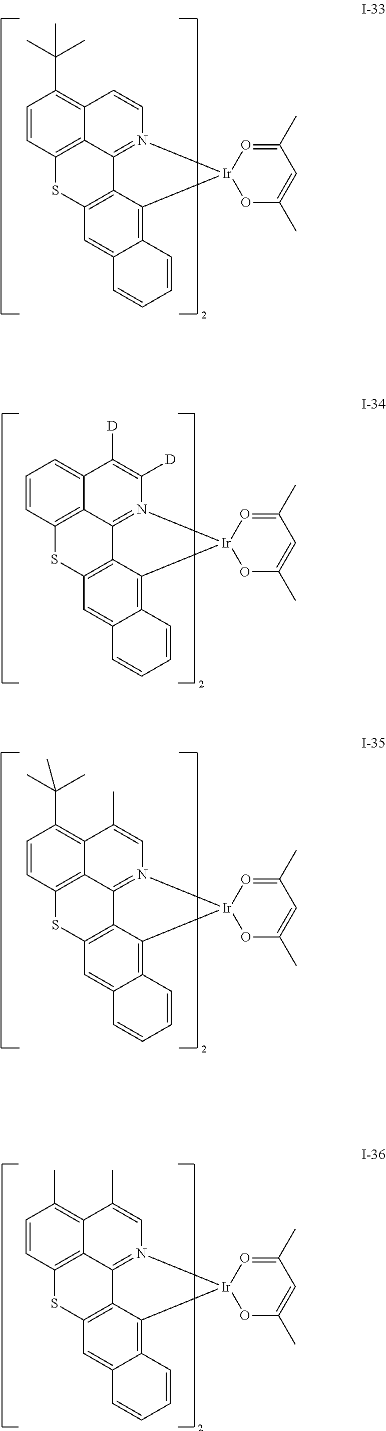

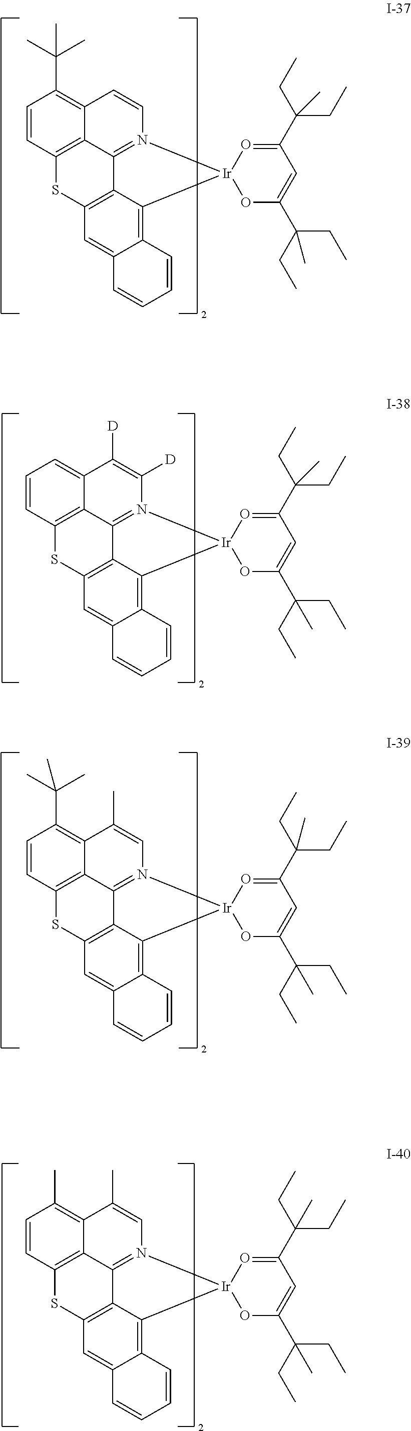

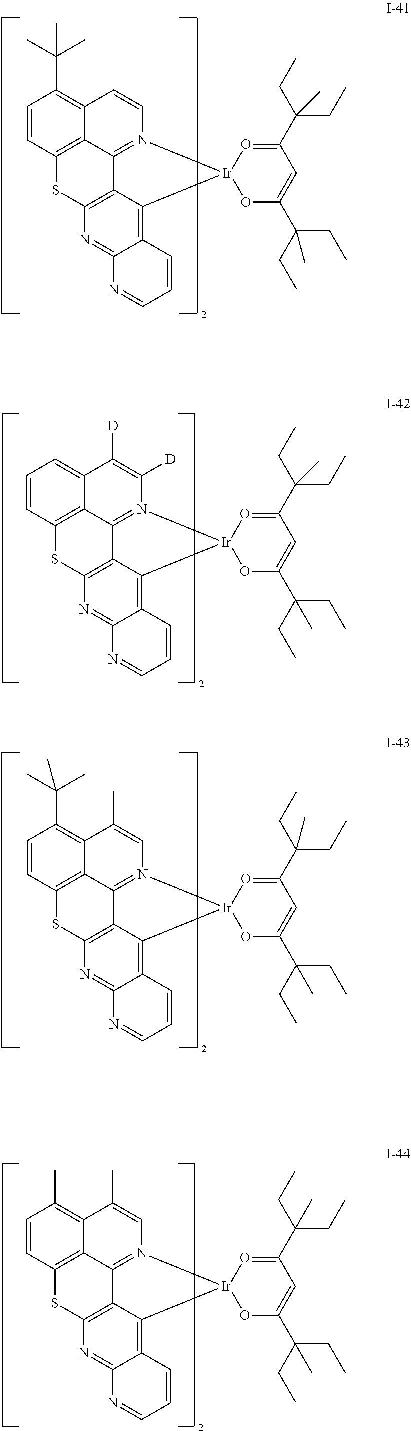

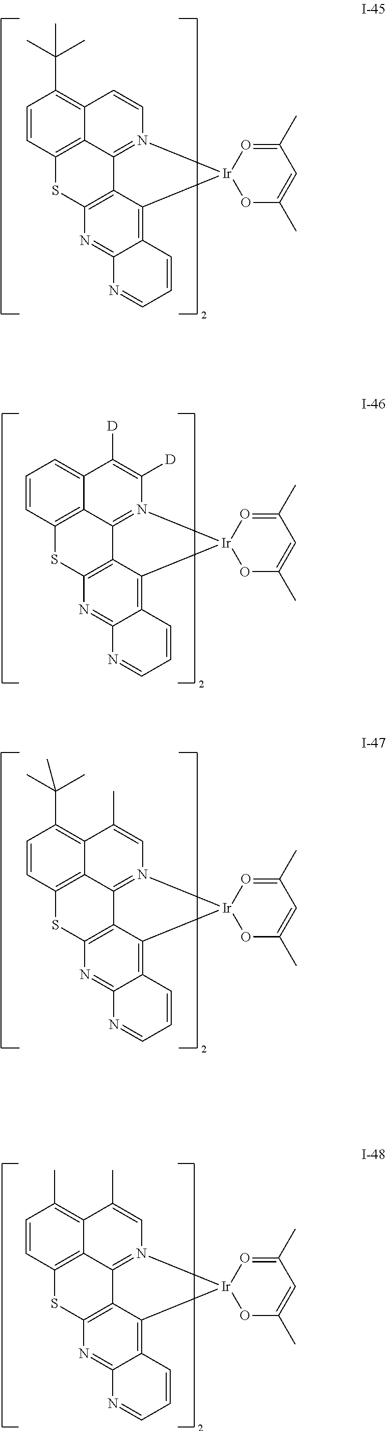

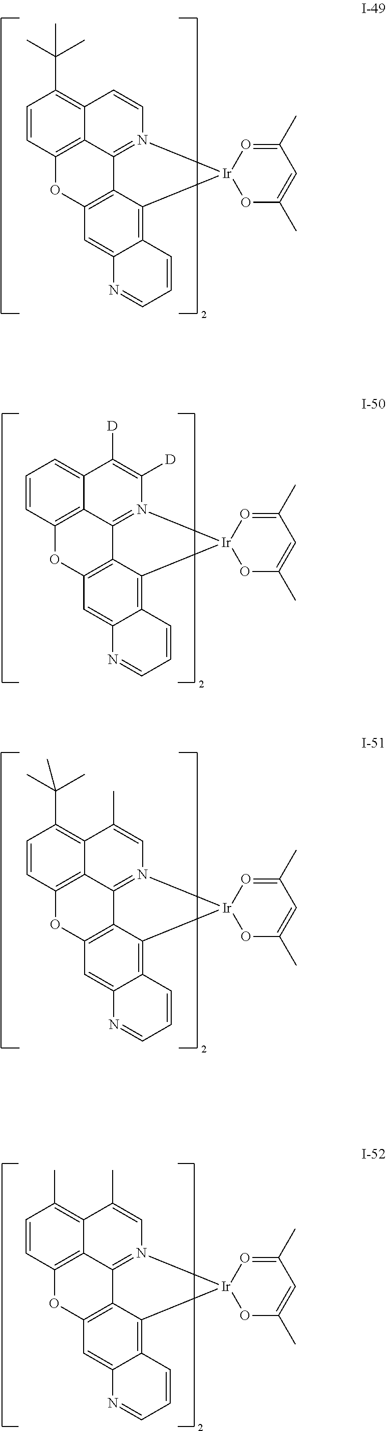

Embodiments of the present disclosure provide a phosphorescent material. The phosphorescent material includes a heterocyclic ligand phosphorescent iridium complex with a structural formula represented by the following general formula I. The phosphorescent material provided by the present disclosure adjusts both the structure of the neutral ligand and the auxiliary ligand to modulate the emission wavelength of the phosphorescent material, thereby effectively suppressing the efficiency roll-off. Therefore, in electroluminescent devices adopting the phosphorescent material, the problem of display color shift caused by efficiency roll-off at high current density is improved.

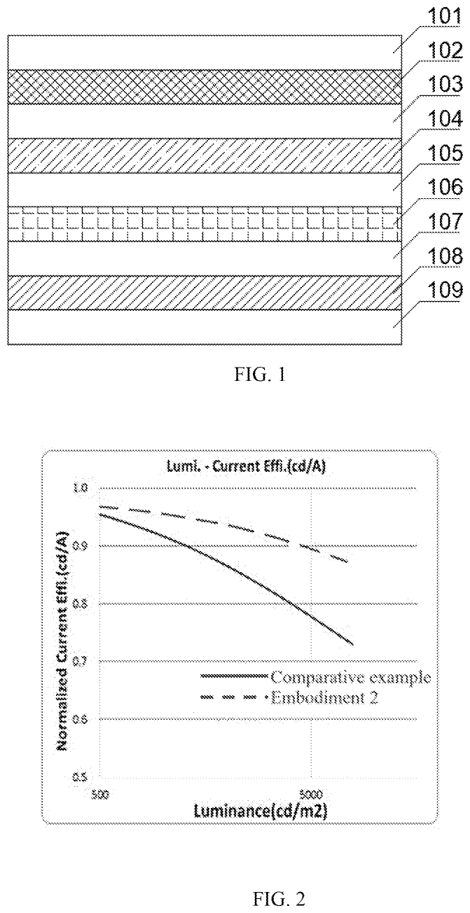

Based on the same creative concept, an embodiment of the present disclosure provides an electroluminescent device. In an optional implementation, the electroluminescent device is a top emission device or a bottom emission device. Taking a top emission device as an example, FIG. 1 is a schematic diagram schematically illustrating an electroluminescent device proposed by the present disclosure. As shown in FIG. 1, the electroluminescent device includes an anode 109, a cathode 101 and at least one emitting layer (EML) 105. The light emitting layer 105 is disposed between the anode 109 and the cathode 101, and the light emitting layer 105 includes the phosphorescent material described in the embodiment of the present disclosure. Specifically, the light emitting layer 105 includes a host luminescent material and a guest luminescent material, and the phosphorescent material is at least one of the host luminescent material and the guest luminescent material.

In some embodiments, the electroluminescent device includes: a hole injection layer (HIL) 108, a hole transport layer (HTL) 107, and an electron blocking layer (EBL) 106 that are sequentially disposed between the anode 109 and the light emitting layer 105 along a first direction, the first direction being a direction pointing to the cathode 101 from the anode 109; and a hole blocking layer (HBL) 104, an electron transport layer (ETL) 103, and an electron injection layer (EIL) 102 that are sequentially disposed between the light emitting layer 105 and the cathode 101 along the first direction.

The hole blocking layer 104 is configured to block holes from the anode 109 at an interface of the light emitting layer 105, so as to increase the probability of recombination of electrons and holes at the interface of the light emitting layer 105, thereby increasing the luminous efficiency of the electroluminescent device. The electron blocking layer 106 is configured to block electrons from the cathode 101 at an interface of the light emitting layer 105, so as to increase the electron concentration at the cross section of the light emitting layer 105.

In an optional implementation, the anode may made from a material with a high work function. For example, for the top emission device, the anode may be ITO (indium tin oxide). IZO (indium zinc oxide) or a composite structure of metal and transparent oxide (e.g., Ag/ITO, Ag/IZO, Al/ITO, AL/IZO, ITO/Ag/TTO, etc.).

In an optional implementation, the material of the cathode may be a low-work-function metal (such as Al, Ag, Mg) or an alloy including a low-work-function metal material.

In an optional implementation, the material of the hole injection layer includes inorganic oxide, p-type dopant or hole transport material. Exemplarily, the p-type dopant may be hexacyanogrouphexaazatriphenylene, 2, 3, 5, 6-tetrafluoro-7, 7, 8, 8-tetracyanogroupquinodimethane (F4TCNQ), 1, 2, 3-tris[(cyanogroup)(4-cyanogroup-2, 3, 5, 6-tetrafluorophenyl)methylene]cyclopropane, and the like; the hole transport material includes any one or more of aromatic amine hole transport materials, dimethyl fluorene hole transport materials or carbazole hole transport materials. Preferably, the material of the hole injection layer may be selected from any one or more of the following compounds 1 and 2:

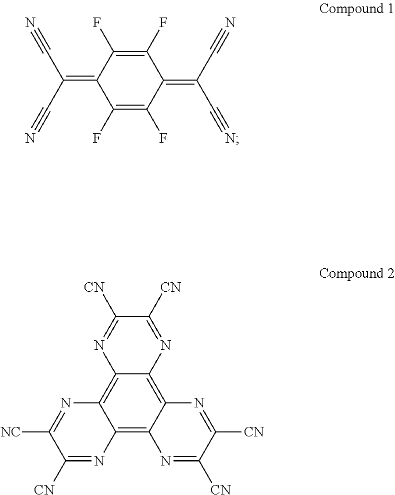

In an optional implementation, the hole transport layer may be formed by vacuum evaporation, and the material of the hole transport layer may be any one or more of an aromatic amine hole transport material, a dimethyl fluorene hole transport material or a carbazole hole transport material. Preferably, the material of the hole transport layer may be selected from any one or more of the following compounds 3 to 5:

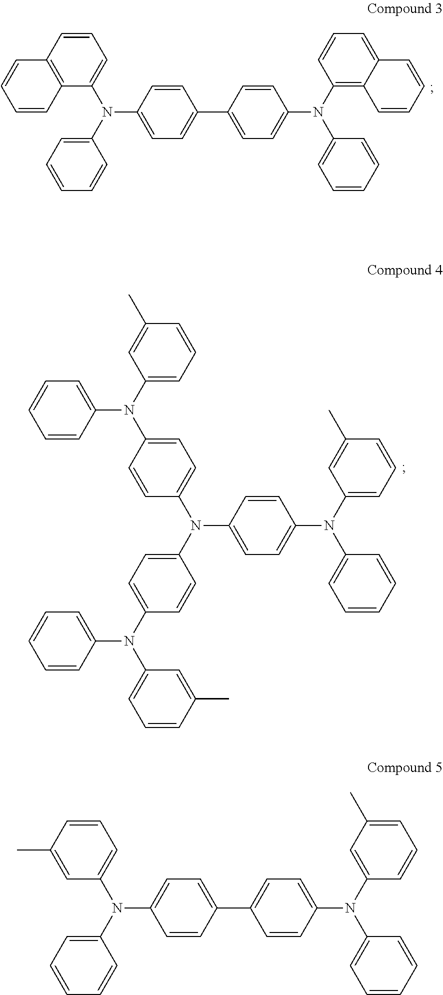 [SMILES: c1ccc(N(c2ccc(-c3ccc(N(c4ccccc4)c4cccc5ccccc45)cc3)cc2)c2cccc3ccccc23)cc1 ; Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1 ; Cc1cccc(N(c2ccccc2)c2ccc(-c3ccc(N(c4ccccc4)c4cccc(C)c4)cc3)cc2)c1]

In an optional implementation, the electron blocking layer may be formed by vacuum evaporation, and the material of the electron blocking layer may be any one or more of an aromatic amine hole transport material, a dimethyl fluorene hole transport material, or a carbazole hole transport material. Preferably, the material of the electron blocking layer may be selected from any one or more of the following compounds 6 and 7:

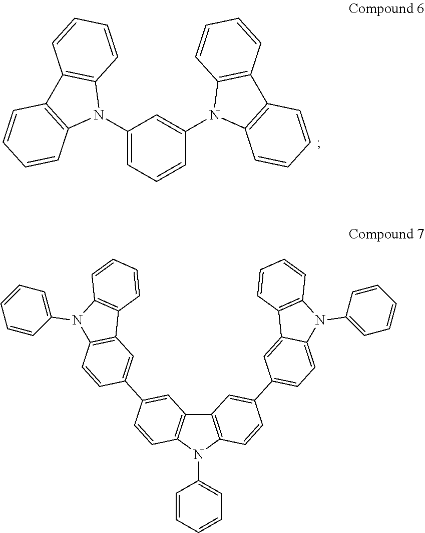 [SMILES: c1cc(-n2c3ccccc3c3ccccc32)cc(-n2c3ccccc3c3ccccc32)c1 ; c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1]

In an optional implementation, the light emitting layer may be formed by vacuum evaporation, the electroluminescent device is a red electroluminescent device, the material of the light emitting layer of the red electroluminescent device includes a red luminescent material. The red luminescent material includes a host luminescent material and a guest luminescent material, and at least one of the host luminescent material and the guest luminescent material is the phosphorescent material. When the guest luminescent material is the phosphorescent material provided in the embodiment of the present disclosure, the host luminescent material may be selected from any one or more of the following compounds 8 to 11:

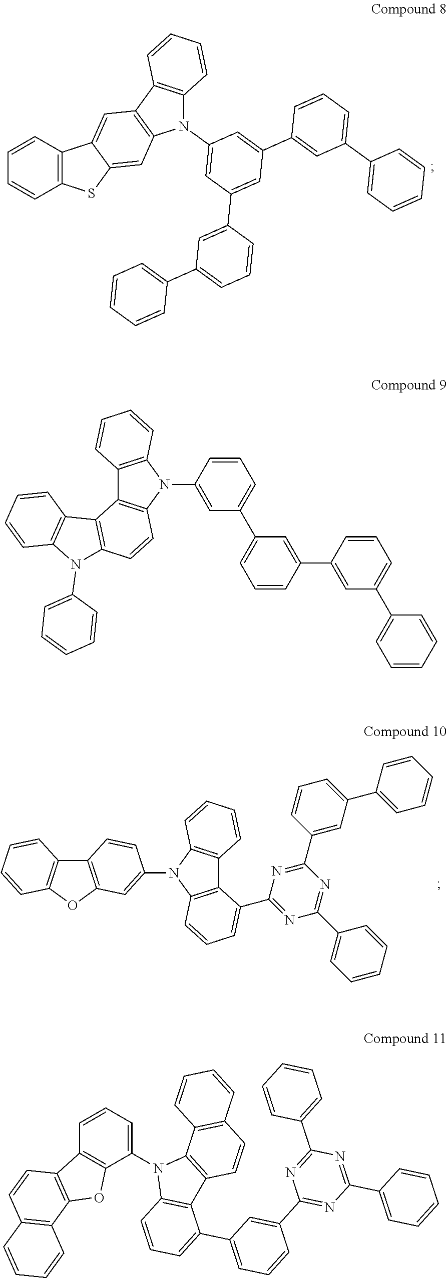 [SMILES: c1ccc(-c2cccc(-c3cc(-c4cccc(-c5ccccc5)c4)cc(-n4c5ccccc5c5cc6c(cc54)sc4ccccc46)c3)c2)cc1 ; c1ccc(-c2cccc(-c3cccc(-c4cccc(-n5c6ccccc6c6c7c8ccccc8n(-c8ccccc8)c7ccc65)c4)c3)c2)cc1 ; c1ccc(-c2cccc(-c3nc(-c4ccccc4)nc(-c4cccc5c4c4ccccc4n5-c4ccc5c(c4)oc4ccccc45)n3)c2)cc1 ; c1ccc(-c2nc(-c3ccccc3)nc(-c3cccc(-c4cccc5c4c4ccc6ccccc6c4n5-c4cccc5c4oc4c6ccccc6ccc54)c3)n2)cc1]

In an optional implementation, the hole blocking layer may be formed by vacuum evaporation, and the material of the hole blocking layer includes aromatic heterocyclic compound hole blocking layer materials. The aromatic heterocyclic compound hole blocking layer materials include any one or more of benzimidazole derivative hole blocking layer materials, triazine derivative hole blocking layer materials, pyrimidine derivative hole blocking layer materials, pyridine derivative hole blocking layer materials, pyrazine derivative hole blocking layer materials, quinoxaline derivative hole blocking layer materials, quinoline derivative hole blocking layer materials, dazole derivative hole blocking layer materials, diazaphospholene derivative hole blocking layer materials, phosphine oxide derivative hole blocking layer materials, aromatic ketone derivative hole blocking layer materials, lactam derivative hole blocking layer materials, and borane derivative hole blocking layer materials. Preferably, the hole blocking layer material may be selected from any one or more of the following compounds 12 and 13:

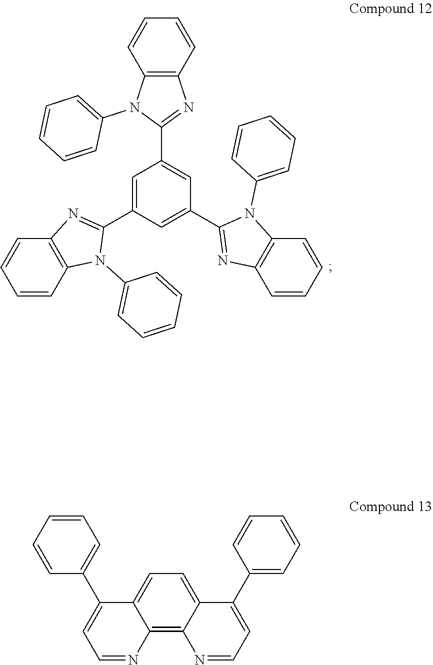 [SMILES: c1ccc(-n2c(-c3cc(-c4nc5ccccc5n4-c4ccccc4)cc(-c4nc5ccccc5n4-c4ccccc4)c3)nc3ccccc32)cc1 ; c1ccc(-c2ccnc3c2ccc2c(-c4ccccc4)ccnc23)cc1]

In an optional implementation, the electron transport layer may be formed by vacuum evaporation, and the material of the electron transport layer includes aromatic heterocyclic compound electron transport layer materials. The aromatic heterocyclic compound electron transport layer materials include any one or more of benzimidazole derivative electron transport layer materials, triazine derivative electron transport layer materials, pyrimidine derivative electron transport layer materials, pyridine derivative electron transport layer materials, pyrazine derivative electron transport layer materials, quinoxaline derivative electron transport layer materials, quinoline derivative electron transport layer materials, diazole derivative electron transport layer materials, diazaphospholene derivative electron transport layer materials, phosphine oxide derivative electron transport layer materials, aromatic ketone derivative electron transport layer materials, lactam derivative electron transport layer materials, and borane derivative electron transport layer materials. Preferably, the material of the electron transport layer may be selected from any one or more of the following compounds 12 to 14, and doped with any one or more of the following compound 15 or lithium fluoride LiF, the doping ratio being (4˜6):(6˜4):

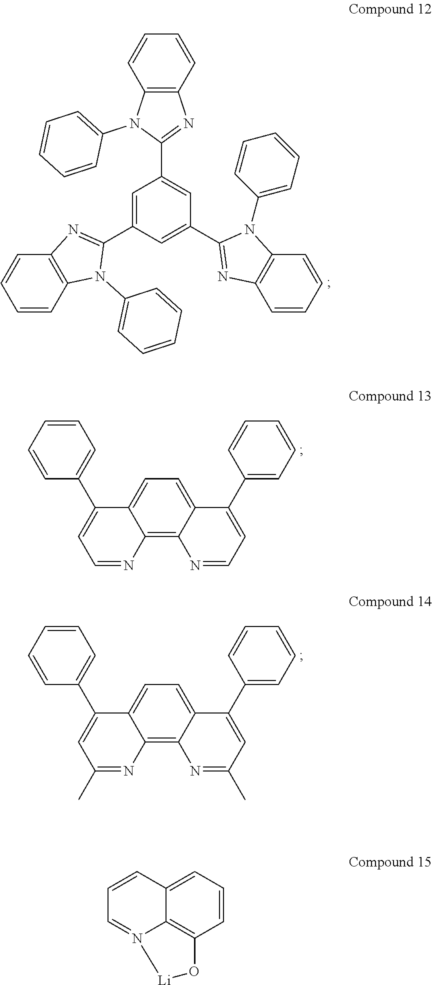

In an optional implementation, the electron injection layer may be formed by vacuum evaporation. The electron injection layer includes any one or more of alkali metal electron injection layer materials or metal electron injection layer materials. For example, the electron injection layer may adopt LiF, Yb, Mg, Ca and their compounds, etc. Preferably, the electron injection layer may adopt any one or more of LiF, Yb and the above compound 15.

In an optional implementation, the thickness of the electron injection layer is in a range of 0.5 nm to 3 nm; the thickness of the electron transport layer is in a range of 20 nm to 35 nm; the thickness of the electron blocking layer is in a range of 5 nm to 80 nm; the thickness of the light emitting layer is in a range of 30 nm to 50 nm; the thickness of the hole blocking layer is in a range of 5 nm to 10 nm; the thickness of the hole transport layer is in a range of 80 nm to 130 nm; the thickness of the hole injection layer is in a range of 5 nm to 30 nm. It should be noted that, when the thicknesses of the electron injection layer, electron transport layer, electron blocking layer, light emitting layer, hole blocking layer, hole transport layer and hole injection layer in the electroluminescent device are within the above ranges, the colors of the light emitted by the electroluminescent device change within the same color system.

In an optional implementation, the electroluminescent device is prepared by evaporation. For example, under a vacuum degree of 5*10⁻⁶ torr, the electroluminescent device is prepared by evaporating the material on ITO with a resistance of 25 Ωsquare⁻¹ through a vacuum evaporation method. It should be noted that the above example is an optional implement to enable those skilled in the art to better understand the solution of the present disclosure. The specific preparation method of the electroluminescent device may be determined according to the actual situation, which is not limited in the present disclosure.

In order to enable those skilled in the art to better understand the performance of the electroluminescent device provided by the embodiments of the present disclosure, the performances of the electroluminescent devices in some exemplary embodiments will be tested and compared below. For the examples (Example 1, Example 2, Example 3) and comparative example 1, except for the guest luminescent material of the light emitting layer, materials of other layers adopt any one or more of the corresponding optional materials of various layer structures mentioned above. The guest luminescent materials of the light emitting layer in the electroluminescent devices of Examples 1, 2 and 3 respectively adopt the I-1 complex, I-27 complex, and I-46 complex among the above-mentioned heterocyclic ligand phosphorescent iridium complexes; the guest luminescent material of the light emitting layer in the electroluminescent device of comparative example 1 adopts the following compound:

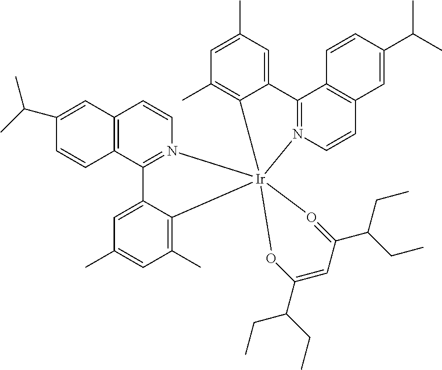

Table 1 shows a comparison of performance data between the electroluminescent device embodiments and the comparative example, as shown in Table 1:

TABLE 1
Comparison of performance data between the electroluminescent
device embodiments and the comparative example

| Guest | Drive | Current | Current | EL | | LT95@ |
|---|---|---|---|---|---|---|
| luminescent | voltage | density | efficiency | peak | FWHM | 35° C. |
| material of EML | (V) | (mA/cm²) | (cd/A) | (nm) | (nm) | (35 mA/cm²) |
| Comparative | 3.64 | 15 | 36.04 | 619 | 28.6 | 275 |
| example 1 | | | | | | |
| Example 1 (I-1) | 3.65 | 15 | 43.37 | 618 | 25 | 213 |
| Example 2 (I-27) | 3.68 | 15 | 44.53 | 618 | 25.1 | 297 |
| Example 3 (I-46) | 3.61 | 15 | 40.57 | 617 | 25.1 | 218 |

As can be seen from the data in Table 1, compared with the electroluminescent device of comparative example 1, the current efficiency of the electroluminescent device that adopts the heterocyclic ligand phosphorescent iridium complex provided in the embodiment of the present disclosure as the guest luminescent material of the light emitting layer is significantly increased. Specifically, the current efficiency of Example 1, Example 2 and Example 3 reaches more than 40 cd/A, while the current efficiency of the comparative example is only 36.04 cd/A. Therefore, the efficiency roll-off may be effectively suppressed by the electroluminescent device that adopts the heterocyclic ligand phosphorescent iridium complex provided in the embodiments of the present disclosure as the guest luminescent material of the light emitting layer. In addition, the full width at half maximum (FWHM) of the electroluminescent device that adopts the heterocyclic ligand phosphorescent iridium complex provided in the embodiments of the present disclosure as the guest luminescent material of the light emitting layer is narrow, and phosphorescence with good color purity can be obtained.

FIG. 2 is a diagram schematically illustrating a Current efficiency-Luminance curve of an electroluminescent device proposed by the present disclosure. As shown in FIG. 2, the vertical axis indicates the current efficiency, and the horizontal axis indicates the luminance. Compared with the current efficiency-luminance curve of the electroluminescent device of comparative example 1, a descend range of the current efficiency of the electroluminescent device of Example 2 (using the I-27 complex as the guest luminescent material) caused due to the increase in the luminance is smaller. Therefore, the efficiency roll-off may be effectively suppressed by the electroluminescent device that adopts the heterocyclic ligand phosphorescent iridium complex provided in the embodiments of the present disclosure as the guest luminescent material of the light emitting layer.

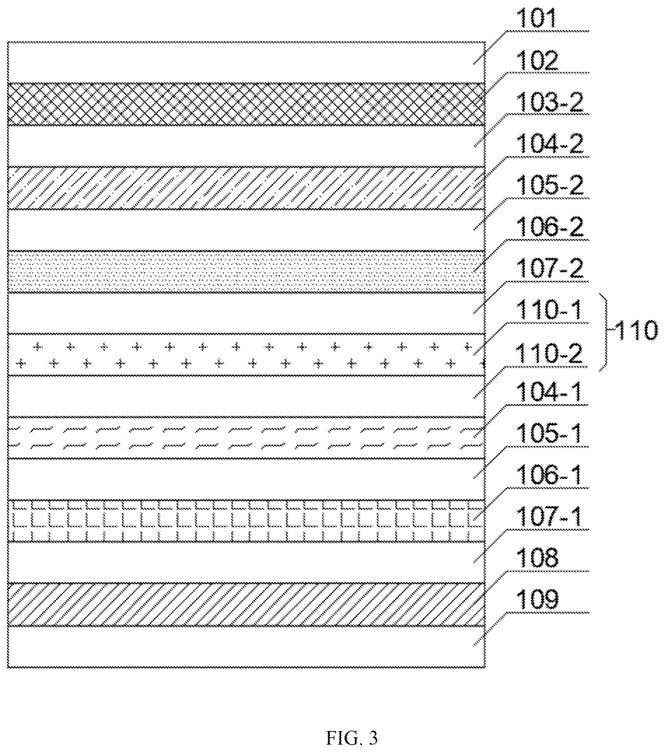

In an optional implementation, FIG. 3 is a schematic diagram schematically illustrating a tandem electroluminescent device proposed by the present disclosure. As shown in FIG. 3, the light emitting layer 105 includes a first light emitting layer 105-1 and a second light emitting layer 105-2. The material of at least one of the first light emitting layer 105-1 and the second light emitting layer 105-2 is the phosphorescent material described in the embodiments of the present disclosure.

In some embodiments, the electroluminescent device includes: a charge generation layer 110, disposed between the first light emitting layer 105-1 and the second light emitting layer 105-2, and including a p-type charge generation layer 110-1 and n-type charge generation layer 110-2; a hole injection layer 108, a first hole transport layer 107-1 and a first electron blocking layer 106-1 that are sequentially disposed between the anode 109 and the first light emitting layer 105-1 along a first direction, where the first direction is a direction pointing from the anode 109 to the cathode 101; a second hole blocking layer 104-2, a second electron transport layer 103-2 and an electron injection layer 102 that are sequentially disposed between the cathode 101 and the second light emitting layer 105-2 along the first direction; a first hole blocking layer 104-1 disposed between the first light emitting layer 105-1 and the n-type charge generation layer 110-2; and a second hole transport layer 107-2 and a second electron blocking layer 106-2 that are sequentially disposed between the p-type charge generation layer 110-1 and the second light emitting layer 105-2 along the first direction.

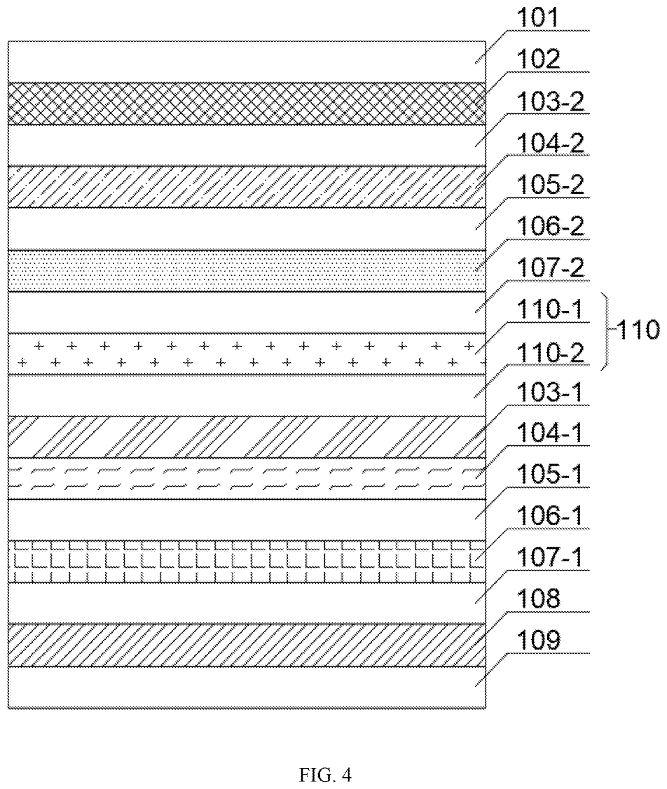

In an optional implementation, FIG. 4 is a schematic diagram schematically illustrating another tandem electroluminescent device proposed by the present disclosure. As shown in FIG. 4, the electroluminescent device further includes a first electron transport layer 103-1 that is disposed between the n-type charge generation layer 110-2 and the hole blocking layer 104-1.

In an optional implementation, the anode may be made from a material with a high work function. For example, for a top emission device, the anode may be ITO (indium tin oxide), IZO (indium zinc oxide) or a composite structure of metal and transparent oxide (e.g., Ag/ITO, Ag/IZO, Al/ITO, A/IZO, ITO/Ag/ITO, etc.).

In an optional implementation, the material of the cathode may be a low-work-function metal (such as Al, Ag, Mg) or an alloy including a low-work-function metal material.

In an optional implementation, the material of the hole injection layer includes inorganic oxide, p-type dopant or hole transport material. Exemplarily, the p-type dopant may be hexacyanogrouphexaazatriphenylene, 2, 3, 5, 6-tetrafluoro-7, 7, 8, 8-tetracyanogroupquinodimethane (F4TCNQ), 1, 2, 3-tris[(cyanogroup)(4-cyanogroup-2, 3, 5, 6-tetrafluorophenyl)methylene]cyclopropane, and the like; the hole transport material includes any one or more of aromatic amine hole transport materials, dimethyl fluorene hole transport materials or carbazole hole transport materials. Preferably, the material of the hole injection layer may be selected from any one or more of the above compounds 1 and 2.

In an optional implementation, the first hole transport layer and the second hole transport layer may be formed by vacuum evaporation, and the material of the first hole transport layer and the second hole transport layer may be any one or more of arylamine hole transport materials, dimethyl fluorene hole transport materials or carbazole hole transport materials. Preferably, the materials of the first hole transport layer and the second hole transport layer may be selected from any one or more of the above compounds 3 to 5.

In an optional implementation, the first electron blocking layer and the second electron blocking layer may be formed by vacuum evaporation, and the materials of the first electron blocking layer and the second electron blocking layer may be any one or more of arylamine hole transport materials, dimethyl fluorene hole transport materials or carbazole hole transport materials. Preferably, the materials of the first electron blocking layer and the second electron blocking layer may be selected from any one or more of the above-mentioned compounds 6 and 7.

In an optional implementation, the first light emitting layer and the second light emitting layer may be formed by vacuum evaporation, the electroluminescent device is a red electroluminescent device, the material of the light emitting layer of the red electroluminescent device includes a red luminescent material. The red luminescent material includes a host luminescent material and a guest luminescent material, and at least one of the host luminescent material and the guest luminescent material is the phosphorescent material. When the guest luminescent material of at least one of the first light emitting layer and the second light emitting layer is the phosphorescent material provided by the embodiment of the present disclosure, the host luminescent material may be selected from any one or more of the above-mentioned compound 8 to compound 11.

In an optional implementation, the first hole blocking layer and the second hole blocking layer may be formed by vacuum evaporation. The materials of the first hole blocking layer and the second hole blocking layer include aromatic heterocyclic compound hole blocking layer materials. The aromatic heterocyclic compound hole blocking layer material include any one or more of benzimidazole derivative hole blocking layer materials, triazine derivative hole blocking layer materials, pyrimidine derivative hole blocking layer materials, pyridine derivative hole blocking layer materials, pyrazine derivative hole blocking layer materials, quinoxaline derivative hole blocking layer materials, quinoline derivative hole blocking layer materials, dazole derivative hole blocking layer materials, diazaphospholene derivative hole blocking layer materials, phosphine oxide derivative hole blocking layer materials, aromatic ketone derivative hole blocking layer materials, lactam derivative hole blocking layer materials, borane derivative hole blocking layer materials. Preferably, the materials of the first hole blocking layer and the second hole blocking layer may be selected from any one or more of the above-mentioned compounds 12 and 13.

In an optional implementation, the first electron transport layer and the second electron transport layer may be formed by vacuum evaporation, the materials of the first electron transport layer and the second electron transport layer include aromatic heterocyclic compound electron transport layer materials. The aromatic heterocyclic compound electron transport layer materials include any one or more of benzimidazole derivative electron transport layer materials, triazine derivative electron transport layer materials, pyrimidine derivative electron transport layer materials, pyridine derivative electron transport layer materials, pyrazine derivative electron transport layer materials, quinoxaline derivative electron transport layer materials, quinoline derivative electron transport layer materials, diazole derivative electron transport layer materials, diazaphospholene derivative electron transport layer materials, phosphine oxide derivative electron transport layer materials, aromatic ketone derivative electron transport layer materials, lactam derivative electron transport layer materials, borane derivative electron transport layer materials. Preferably, the materials of the first electron transport layer and the second electron transport layer may be selected from any one or more of the above-mentioned compounds 12 to 14, and are doped with any one or more of the above-mentioned compound 15 and lithium fluoride LiF, the doping ratio is (4˜6):(6˜4).

In an optional implementation, the electron injection layer may be formed by vacuum evaporation. The electron injection layer includes any one or more of alkali metal electron injection layer materials or metal electron injection layer materials. For example, the electron injection layer may adopt LiF, Yb, Mg, Ca and their compounds, etc. Preferably, the electron injection layer may adopt any one or more of LiF, Yb and the above compound 15.

In an optional implementation, the material of the p-type charge generation layer may be selected from any one or more of the following compounds 16 and 17, and is doped with any one or more of the above compounds 1 and 2, the doping ratio is 1% to 5%:

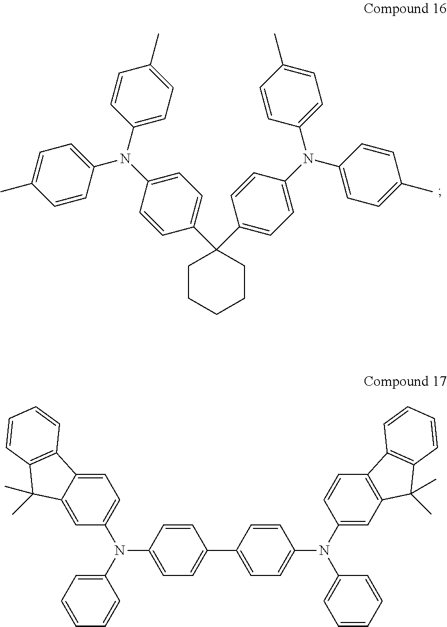

In an optional implementation, the material of the n-type charge generation layer may be selected from any one or more of the following compounds 18 and 19, and is doped with any one or more of Li, Rb, Cs, Mg, MoO₃, WO₃, and V₂O₅, the doping ratio is 0.5%-2%:

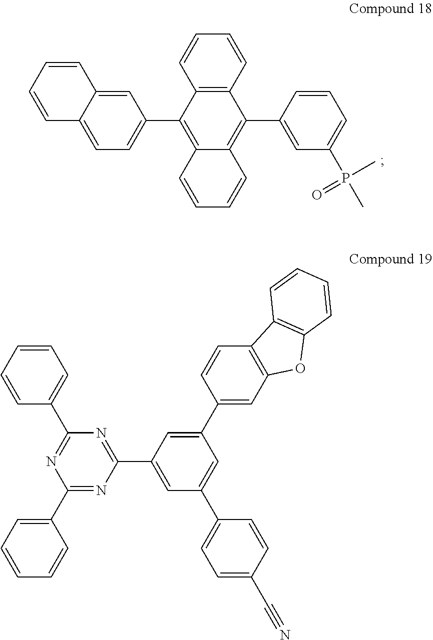 [SMILES: CP(C)(=O)c1cccc(-c2c3ccccc3c(-c3ccc4ccccc4c3)c3ccccc23)c1 ; N#Cc1ccc(-c2cc(-c3ccc4c(c3)oc3ccccc34)cc(-c3nc(-c4ccccc4)nc(-c4ccccc4)n3)c2)cc1]

In an optional implementation, the thickness of the electron injection layer is in a range of 0.5 nm to 3 nm; the thicknesses of the first electron transport layer and the second electron transport layer are in a range of 20 nm to 35 nm; the thicknesses of the first electron blocking layer and the second electron transport layer are in a range of 5 nm to 80 nm; the thicknesses of the first light emitting layer and the second light emitting layer are in a range of 30 nm to 50 nm; the thicknesses of the first hole blocking layer and the second hole blocking layer are in a range of 5 nm to 10 nm; the thicknesses of the first hole transport layer and the second hole transport layer are in a range of 80 nm to 130 nm; the thickness of the hole injection layer is in a range of 5 nm to 30 nm; the thickness of the p-type charge generation layer is in a range of 8 nm to 10 nm; the thickness of the n-type charge generation layer is in a range of 17 nm to 19 nm. It should be noted that, when the thicknesses of the electron injection layer, the first electron transport layer, the second electron transport layer, the first electron blocking layer, the second electron blocking layer, the first light emitting layer, and the second light emitting layer, the first hole blocking layer, the second hole blocking layer, the first hole transport layer, the second hole transport layer and the hole injection layer in the electroluminescent device are within the above ranges, the colors of the emitted light vary within the same color system.

In an optional implementation, the electroluminescent device is prepared by evaporation. For example, under a vacuum degree of 5*10⁻⁶ torr, the electroluminescent device is prepared by evaporating the material on ITO with a resistance of 25 Ωsquare⁻¹ through a vacuum evaporation method. It should be noted that the above example is an optional implement to enable those skilled in the art to better understand the solution of the present disclosure. The specific preparation method of the electroluminescent device may be determined according to the actual situation, which is not limited in the present disclosure.

In order to enable those skilled in the art to better understand the performance of the tandem electroluminescent device provided by the embodiments of the present disclosure, the performances of the tandem electroluminescent devices in some exemplary embodiments will be tested and compared below. For the embodiments (Example 4, Example 5, and Example 6) and Comparative Example 2, except for the guest luminescent material of the first light emitting layer and/or the second light emitting layer, the materials of other layers adopt any one or more of the corresponding optional materials in the various layers. The guest luminescent materials of the first light emitting layer and/or the second light emitting layer in the electroluminescent devices of Embodiment 4, Embodiment 5, and Embodiment 6 respectively adopt the I-1 complex, I-27 complex, I-46 complex among the above heterocyclic ligand posphorescent iridium complexes, and the guest luminescent material of the light emitting layer in the electroluminescent device of Comparative Example 2 adopt the following compounds:

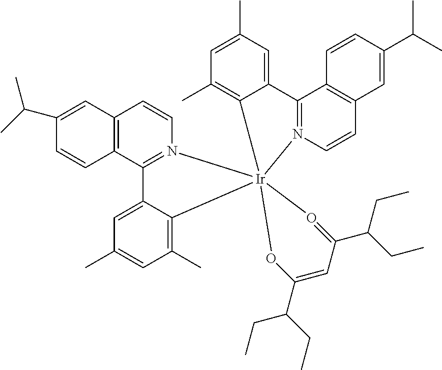

Table 2 shows a comparison of the performance data of the tandem electroluminescent device embodiments and the comparative examples, as shown in Table 2:

TABLE 2
Comparison of the performance data of the tandem electroluminescent
device embodiments and comparative example

| Guest | Drive | Current | Current | EL | | LT80@ |
|---|---|---|---|---|---|---|
| luminescent | voltage | density | efficiency | peak | FWHM | 85°C |
| material of EML | (V) | (mA/cm²) | (cd/A) | (nm) | (nm) | (15 mA/cm²) |
| Comparative | 7.69 | 15 | 57.25 | 632 | 38 | 4000 |
| example 2 | | | | | | |
| Example 4 (I-1) | 7.72 | 15 | 62.43 | 628 | 37 | 4100 |
| Example 5 (I-27) | 7.65 | 15 | 62.59 | 628 | 36 | 4400 |
| Example 6 (I-46) | 7.7 | 15 | 59.35 | 628 | 37 | 4500 |

As can be seen from the data m Table 2, compared with the electroluminescent device of comparative example 2, the current efficiency of the tandem electroluminescent device that adopts the heterocyclic ligand phosphorescent iridium complex provided in the embodiment of the present disclosure as the guest luminescent material of the light emitting layer is significantly increased. Specifically, the current efficiency of Examples 4, 5 and 6 reaches above 58 cd/A, while the current efficiency of Comparative Example 2 is only 57.25 cd/A. Therefore, the efficiency roll-off may be effectively suppressed by the tandem electroluminescent device that adopts the heterocyclic ligand phosphorescent iridium complex provided in the embodiments of the present disclosure as the guest luminescent material of the light emitting layer. In addition, the full width at half maximum (FWHM) of the electroluminescent device that adopts the heterocyclic ligand phosphorescent iridium complex provided in the embodiments of the present disclosure as the guest luminescent material of the light emitting layer is narrow, and phosphorescence with good color purity can be obtained.

Based on the same creative concept, an embodiment of the present disclosure provides a display device including the electroluminescent device described in the embodiments of the present disclosure.

The display device further includes: a pixel definition layer, the electroluminescent device being disposed in the pixel definition layer; an encapsulation layer, disposed on a side of the electroluminescent device facing away from the pixel definition layer. The material of the encapsulation layer may be any one or more of silicon nitride, acrylic/silicon oxynitride and other materials.

The device embodiments described above are only illustrative. Units described as separate components may or may not be physically separated. The components shown as units may or may not be physical units, that is, they may be located in one location, or may be distributed across multiple network units. Some or all of the modules may be selected according to actual needs to achieve the object of the solution of the embodiments. Those skilled in the art may understand and implement the method without paying any creative effort.

References herein to “one embodiment,” “an embodiment.” or “one or more embodiments” mean that a particular feature, structure, or characteristic described in connection with the embodiments is included in at least one embodiment of the present disclosure. Additionally, please note that wordings such as “in one embodiment” herein do not necessarily all refer to the same embodiment.

In the description provided herein, numerous specific details are set forth. However, it is understood that embodiments of the present disclosure may be practiced without these specific details. In some instances, common methods, structures and techniques have not been shown in detail in order not to obscure the understanding of this description.

In the claims, any reference signs placed between parentheses shall not be construed as limiting the claims. The word “comprising” does not exclude the presence of elements or steps not listed in the claims. The word “a” or “an” preceding an element does not exclude the presence of a plurality of such elements. The disclosure may be implemented by means of hardware including several distinct elements and a suitably programmed computer. In a unit claim enumerating several devices, several of these devices may be embodied by the same hardware item. The words such as “first”, “second”, and “third” as used do not indicate any order. These words may be interpreted as names.

Finally, it should be noted that the above embodiments are only used to explain the technical solutions of the present disclosure, rather than limiting them. Although the present disclosure has been described in detail with reference to the foregoing embodiments, those skilled in the art should understand that the technical solutions described in the foregoing embodiments can still be modified, or equivalent replacements for some of the technical features may be made; and these modification or replacement does not make the essence of the corresponding technical solutions deviate from the spirit and scope of the technical solutions of the embodiments of the present disclosure.

1. A phosphorescent material, comprising:
a heterocyclic ligand phosphorescent iridium complex with a structural formula indicated by general formula I below: 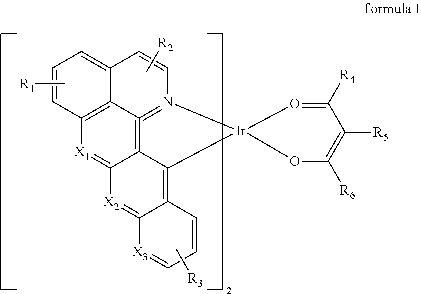
wherein X₁ is O or S, X₂ and X₃ are each independently selected from N or C;
R₁, R₂, R₃, R₄, R₅ and R₆ are each independently selected from hydrogen, deuterium, halogen, cyanogroup, nitro, hydroxy, amino, sulfonic acid group, sulfonyl group, phosphoryl group, substituted or unsubstituted C1-C60 alkyl group, substituted or unsubstituted C6-C60 aryl group, substituted or unsubstituted C3-C30 cycloalkyl group, substituted or unsubstituted C1-C60 alkoxy group, substituted or unsubstituted C1-C60 alkylamine group, substituted or unsubstituted C2-C60 alkenyl, substituted or unsubstituted C2-C60 alkynyl, substituted or unsubstituted C5-C60 heterocyclyl, substituted or unsubstituted C10-C60 condensed cyclic group or substituted or unsubstituted C5-C60 spirocyclic group.

2. The phosphorescent material according to claim 1, wherein a lifetime of excitons of the heterocyclic ligand phosphorescent iridium complex is less than or equal to 1 μs.

3. The phosphorescent material according to claim 1, wherein a ratio of current efficiency of an electroluminescent device at a peak luminance of 16,000 nits to the current efficiency of the electroluminescent device at the peak luminance of 1,300 nits is less than or equal to 0.8, wherein the electroluminescent device comprises a light emitting layer, and the material of the light emitting layer comprises the heterocyclic ligand phosphorescent iridium complex.

4. The phosphorescent material according to claim 1, wherein substitution positions of R₁, R₂ and R₃ are at any position where a ring thereof is located, R₁ and R₃ represent monosubstituted group, bi-substituted group, tri-substituted group or no substituent, R₂, R₅ represent monosubstituted group, bi-substituted group or no substituent, and R₄ and R₆ represent monosubstituted group or no substituent.

5. The phosphorescent material according to claim 1, wherein any adjacent R₁, R₂, R₃ substituent groups form a condensed ring or aromatic heterocyclic ring with the ring where they located, R₁, R₂ and R₃ that do not form a condensed ring or aromatic heterocyclic ring are each independently selected from any one of hydrogen, deuterium, substituted or unsubstituted C1-C60 alkyl group, substituted or unsubstituted C6-C60 aryl group, substituted or unsubstituted C3-C60 cycloalkyl group, substituted or unsubstituted C5-C60 heterocyclyl group, substituted or unsubstituted C10-C60 condensed cyclic group, substituted or unsubstituted C5-C60 spirocyclic group.

6. The phosphorescent material according to claim 1, wherein R₁, R₂, R₃, R₄, R₅ and R₆ are each independently selected from any one of hydrogen, deuterium, substituted or unsubstituted C1-C30 alkyl, substituted or unsubstituted C3-C20 cycloalkyl, substituted or unsubstituted C1-C20 alkoxy group, substituted or unsubstituted C5-C30 heterocyclic group, substituted or unsubstituted C6-C30 aryl group, substituted or unsubstituted C10-C30 condensed cyclic group.

7. The phosphorescent material according to claim 1, wherein R₁ is any one of tert-butyl, methyl, and hydrogen; R₂ is any one of methyl, hydrogen, and deuterium; R₃ is any one of hydrogen, methyl, and tert-butyl; R₄ is any one of hexyl, methyl and isopropyl; R₅ is hydrogen; R6 is any one of hexyl, methyl and isopropyl.

8. The phosphorescent material according to claim 1, wherein the heterocyclic ligand phosphorescent iridium complex is selected from any one of:

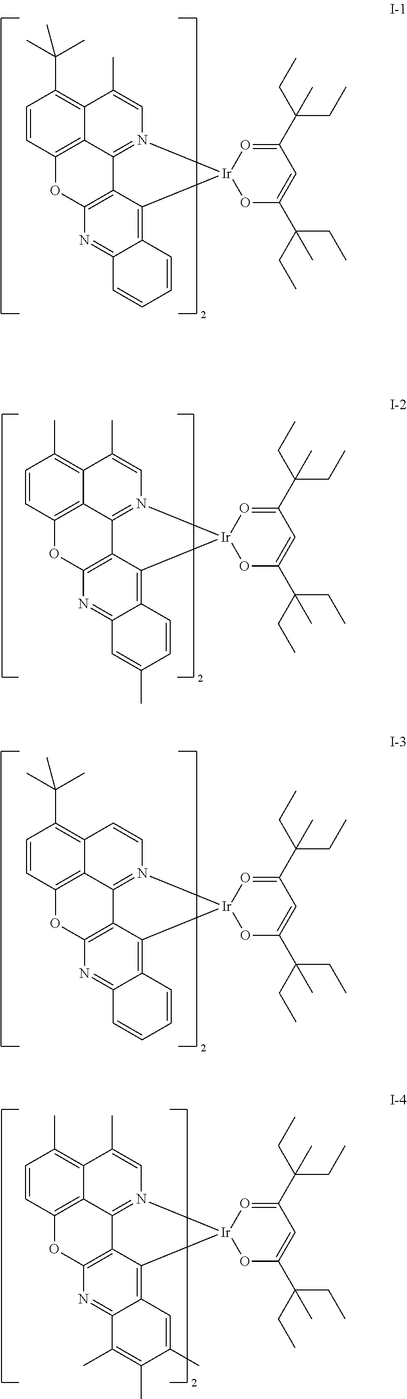

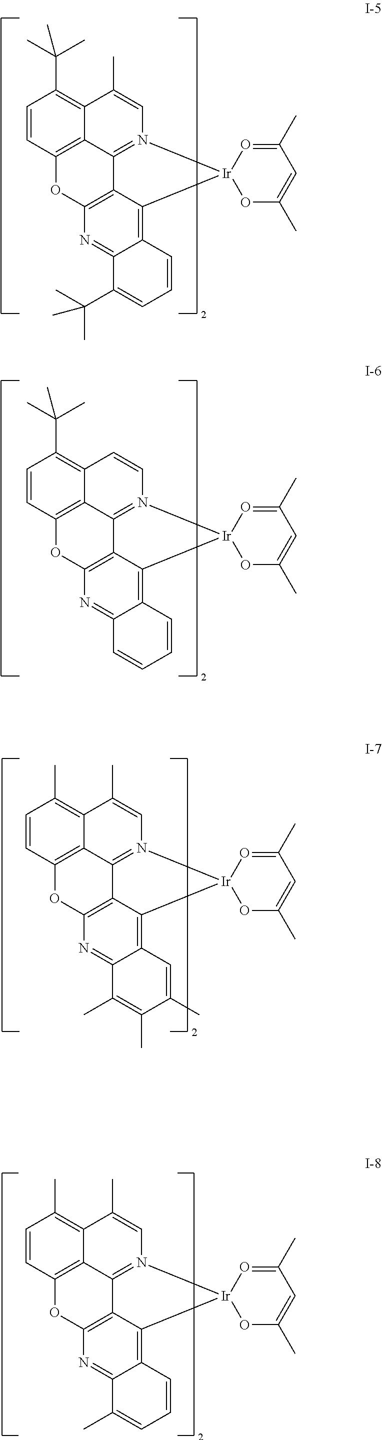

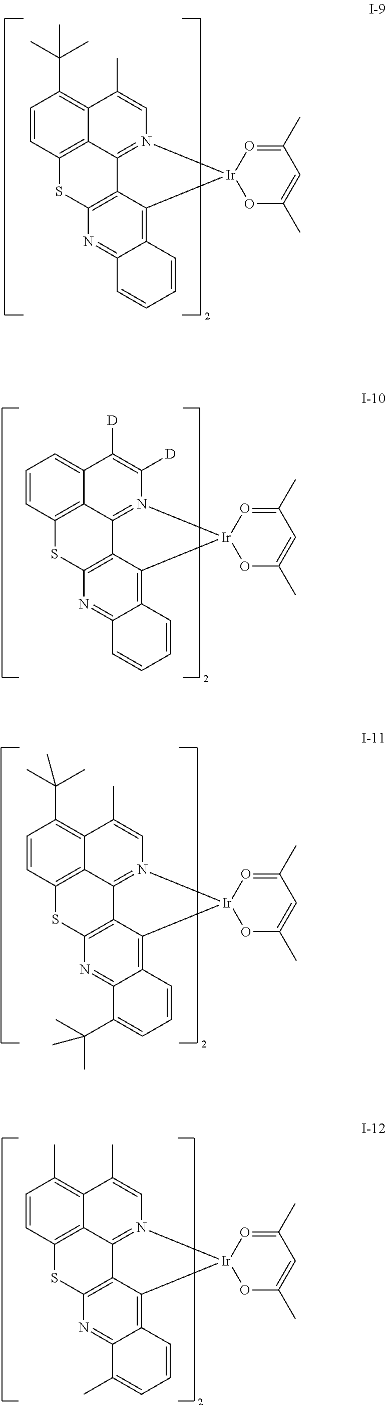

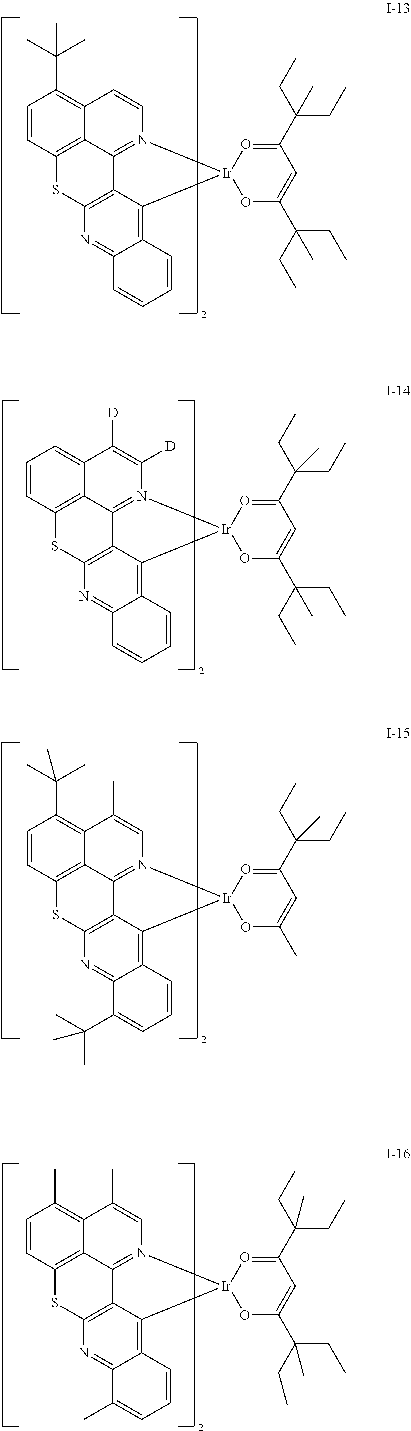

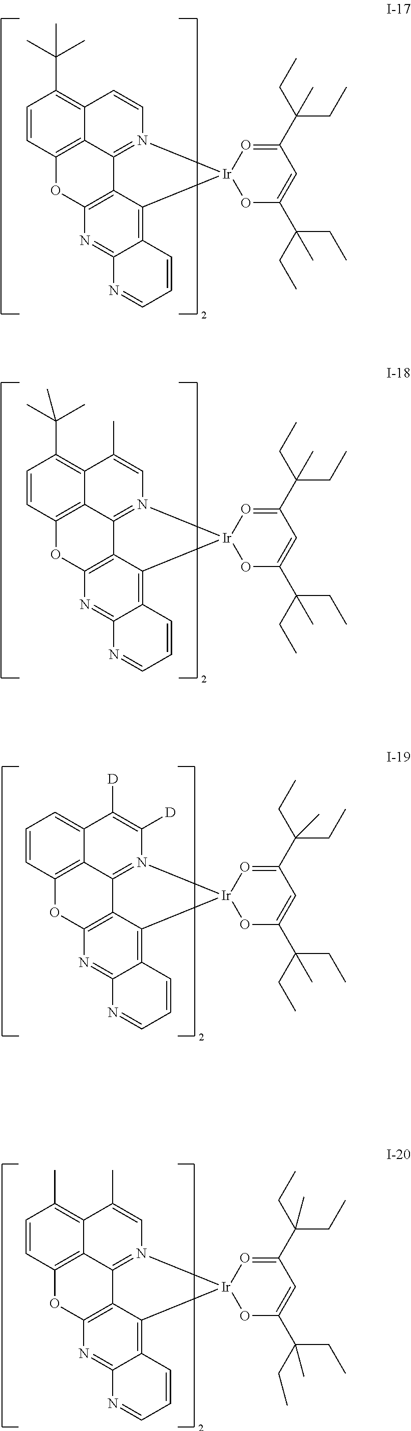

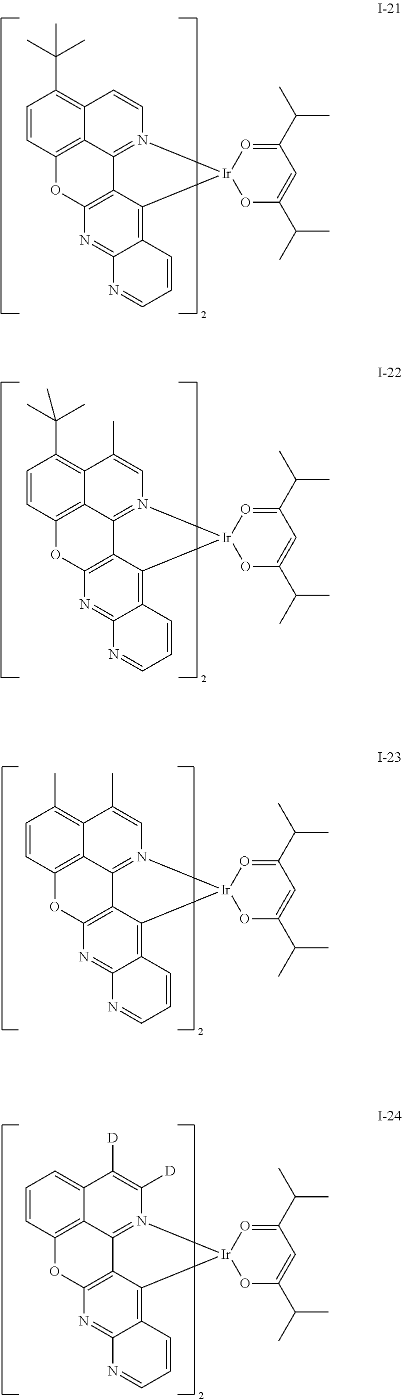

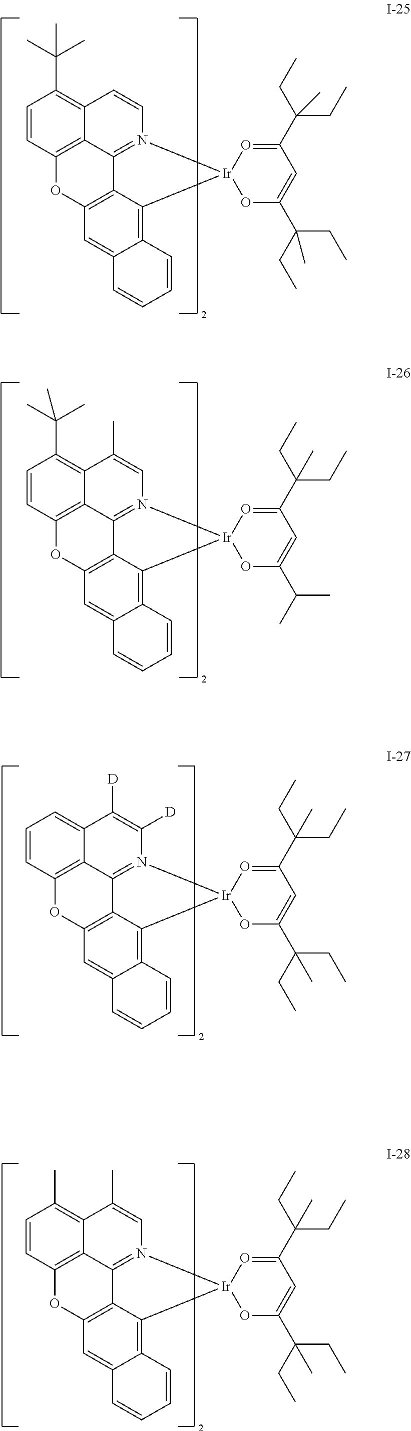

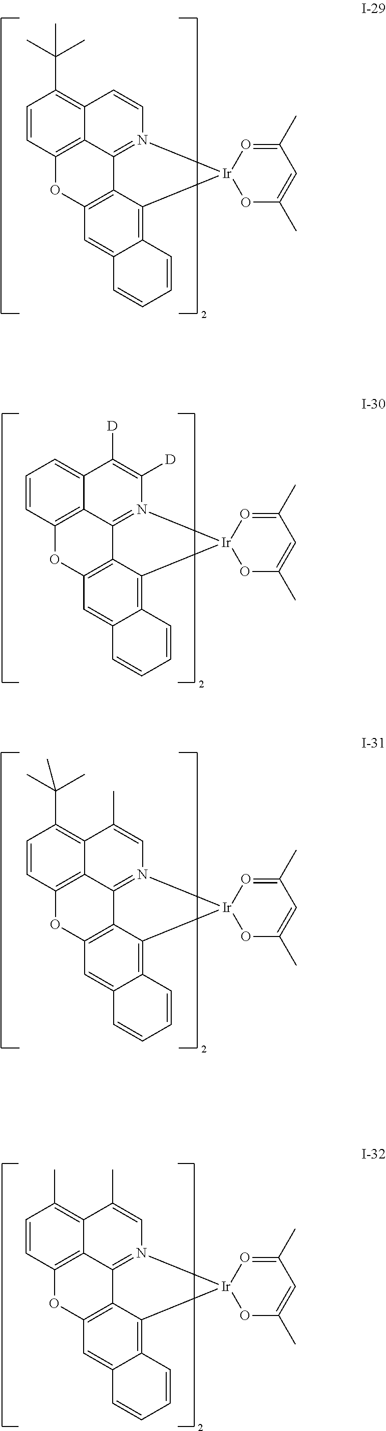

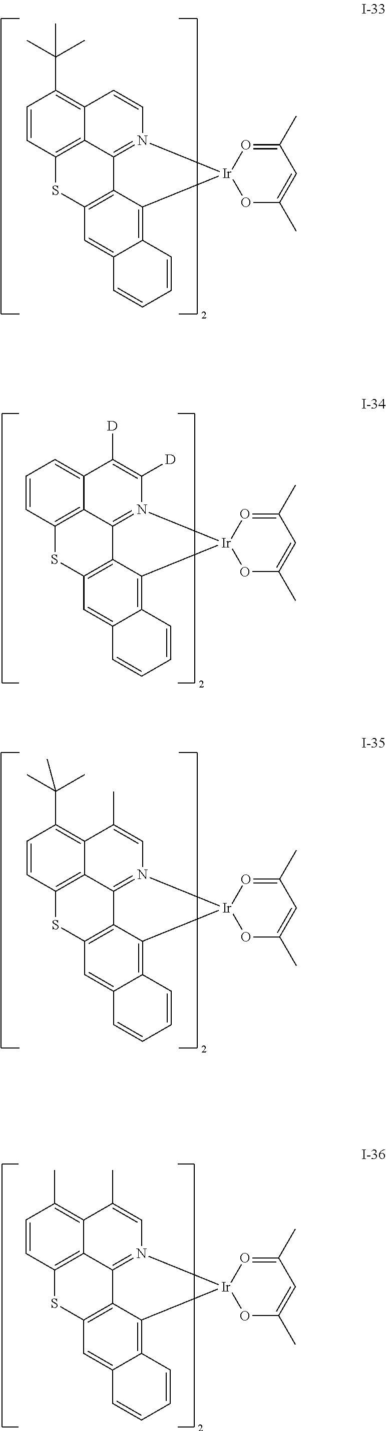

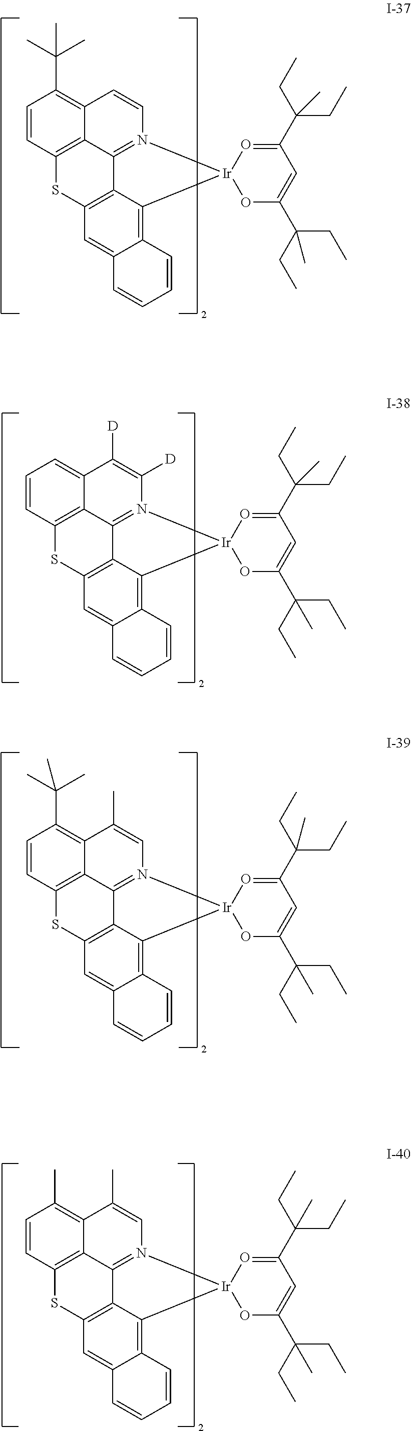

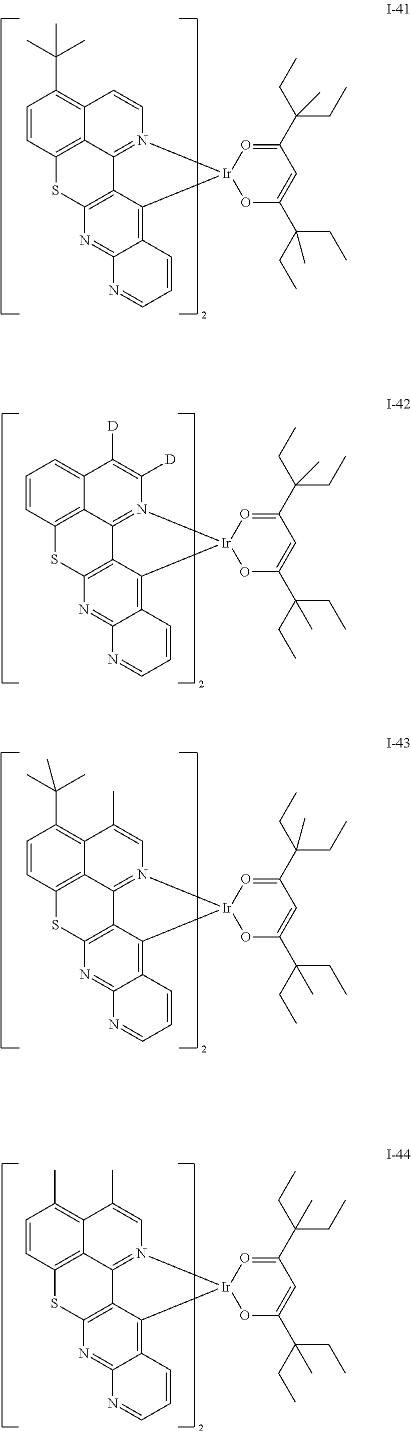

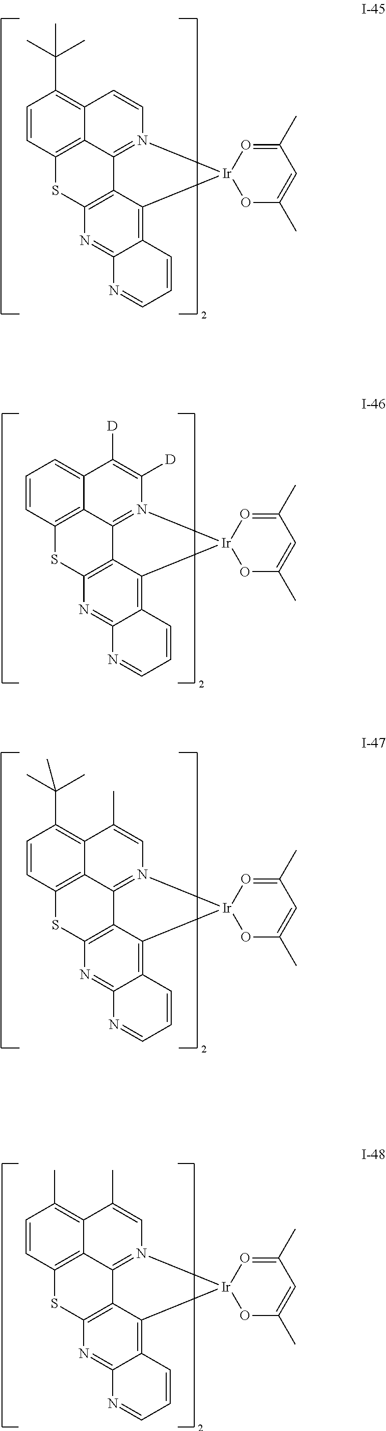

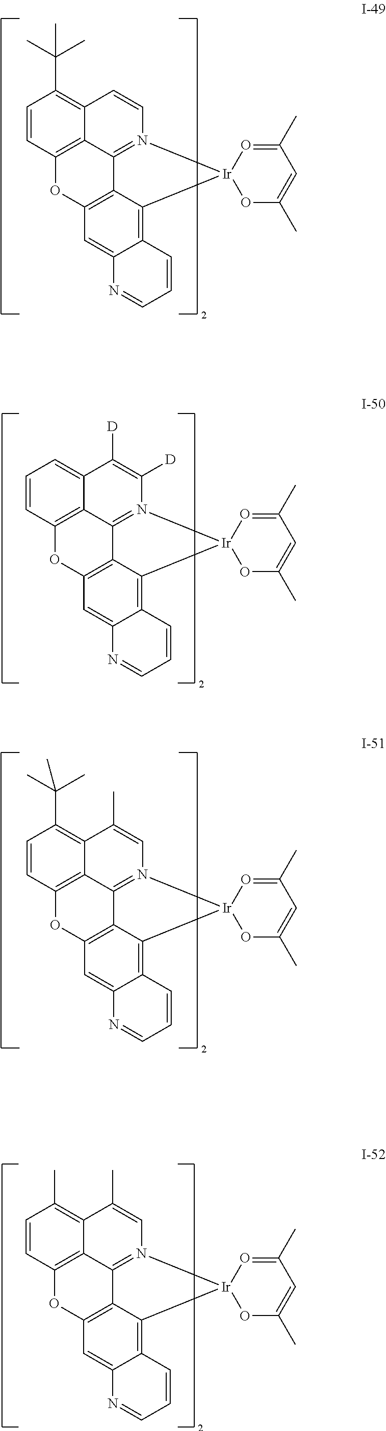

9. An electroluminescent device, comprising:
an anode, a cathode and at least one light emitting layer, wherein the light emitting layer is disposed between the anode and the cathode, and the light emitting layer comprises a phosphorescent material, wherein the phosphorescent material comprises a heterocyclic ligand phosphorescent iridium complex with a structural formula indicated by general formula I below: 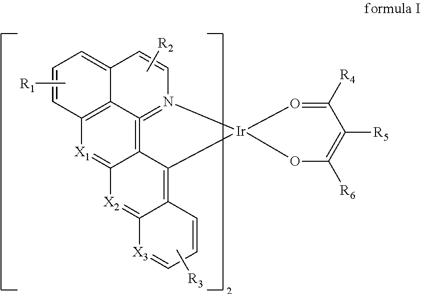
wherein X₁ is O or S, X₂ and X₃ are each independently selected from N or C;
R₁, R₂, R₃, R₄, R₅ and R₆ are each independently selected from hydrogen, deuterium, halogen, cyanogroup, nitro, hydroxy, amino, sulfonic acid group, sulfonyl group, phosphoryl group, substituted or unsubstituted C1-C60 alkyl group, substituted or unsubstituted C6-C60 aryl group, substituted or unsubstituted C3-C30 cycloalkyl group, substituted or unsubstituted C1-C60 alkoxy group, substituted or unsubstituted C1-C60 alkylamine group, substituted or unsubstituted C2-C60 alkenyl, substituted or unsubstituted C2-C60 alkynyl, substituted or unsubstituted C5-C60 heterocyclyl, substituted or unsubstituted C10-C60 condensed cyclic group or substituted or unsubstituted C5-C60 spirocyclic group;
wherein the light emitting layer comprises a host luminescent material and a guest luminescent material, and at least one of the host luminescent material and the guest luminescent material is the phosphorescent material.

10. The electroluminescent device according to claim 9, wherein the electroluminescent device comprises:
a hole injection layer, a hole transport layer and an electron blocking layer that are sequentially disposed between the anode and the light emitting layer along a first direction, the first direction is a direction pointing to the cathode from the anode; and
a hole blocking layer, an electron transport layer, and an electron injection layer that are disposed sequentially between the light emitting layer and the cathode along the first direction.

11. The electroluminescent device according to claim 9, wherein
a thickness of the electron injection layer is in a range of 0.5 nm to 3 nm;
a thickness of the electron transport layer is in a range of 20 nm to 35 nm;
a thickness of the electron blocking layer is in a range of 5 nm to 80 nm;
a thickness of the light emitting layer is in a range of 30 nm to 50 nm;
a thickness of the hole blocking layer is in a range of 5 nm to 10 nm;
a thickness of the hole transport layer is in a range of 80 nm to 130 nm; and
a thickness of the hole injection layer is in a range of 5 nm to 30 nm.

12. The electroluminescent device according to claim 9, wherein the light emitting layer comprises:
a first light emitting layer and a second light emitting layer, wherein the material of at least one of the first light emitting layer and the second light emitting layer is the phosphorescent material.

13. The electroluminescent device according to claim 12, wherein the electroluminescent device comprises:
a charge generation layer, disposed between the first light emitting layer and the second light emitting layer, wherein the charge generation layer comprises a p-type charge generation layer and n-type charge generation layer;
a hole injection layer, a first hole transport layer and a first electron blocking layer that are sequentially disposed between the anode and the first light emitting layer along a first direction, wherein the first direction is a direction pointing to the cathode from the anode;
a second hole blocking layer, a second electron transport layer and an electron injection layer that are sequentially disposed between the cathode and the second light emitting layer along the first direction;
a first hole blocking layer disposed between the first light emitting layer and the n-type charge generation layer; and
a second hole transport layer and a second electron blocking layer that are sequentially disposed between the p-type charge generation layer and the second light emitting layer along the first direction.

14. The electroluminescent device according to claim 13, wherein the electroluminescent device further comprises a first electron transport layer disposed between the n-type charge generation layer and the first hole blocking layer;
a thickness of the electron injection layer is in a range of 0.5 nm to 3 nm;
the thicknesses of the first electron transport layer and the second electron transport layer are in a range of 20 nm to 35 nm;
the thicknesses of the first electron blocking layer and the second electron blocking layer are in a range of 5 nm to 80 nm;
the thicknesses of the first light emitting layer and the second light emitting layer is in a range of 30 nm to 50 nm;
the thicknesses of the first hole blocking layer and the second hole blocking layer are in a range of 5 nm to 10 nm;
the thicknesses of the first hole transport layer and the second hole transport layer are in a range of 80 nm to 130 nm;
the thickness of the hole injection layer is in a range of 5 nm to 30 nm;
the thickness of the p-type charge generation layer is in a range of 8 nm to 10 nm; and
the thickness of the n-type charge generation layer is in a range of 17 nm to 19 nm.

15. A display device, comprising the electroluminescent device according to claim 9.
